(19) United States
(12) Patent Application Publication
(10) Pub. No.: US 2024/0379835 A1
(43) Pub. Date: Nov. 14, 2024

(54) SEMICONDUCTOR DEVICE AND SEMICONDUCTOR MODULE

(71) Applicant: ROHM CO., LTD., Kyoto-shi (JP)

(72) Inventors: Isao TAKOBE, Kyoto-shi (JP); Hirotaka OTAKE, Kyoto-shi (JP)

(21) Appl. No.: 18/782,942

(22) Filed: Jul. 24, 2024

Related U.S. Application Data
(63) Continuation of application No. PCT/JP2022/047072, filed on Dec. 21, 2022.

(30) Foreign Application Priority Data
Jan. 28, 2022 (JP) 2022-012101

(51) Int. Cl. H01L 29/778; H01L 23/00; H01L 27/06; H01L 29/20; H01L 29/423; H01L 29/66

(52) U.S. Cl. CPC H01L 29/7786; H01L 24/32; H01L 24/48; H01L 24/73; H01L 27/0629; H01L 29/2003; H01L 29/42316; H01L 29/66462; H01L 2224/32245; H01L 2224/48257; H01L 2224/73265; H01L 2924/13064

(57) ABSTRACT

A semiconductor device according to the present invention comprises: a semiconductor substrate; a GaN transistor that is formed upon the semiconductor substrate and includes a drain electrode, a source electrode, and a gate electrode; an active clamp circuit that is formed upon the semiconductor substrate, is electrically connected to the GaN transistor, and includes a clamp transistor which operates on the basis of an increase in the drain-source voltage of the GaN transistor; a drain pad that is electrically connected to the drain electrode of the GaN transistor; a main source pad that is electrically connected to the source electrode of the GaN transistor; and a gate pad that is electrically connected to the gate electrode of the GaN transistor.

### CROSS-REFERENCE TO RELATED APPLICATIONS

This application is a continuation of, and claims the benefit of priority from International Application No. PCT/JP2022/047072, filed on Dec. 21, 2022, which claims the benefit of priority from Japanese Patent Application No. 2022-012101, filed on Jan. 28, 2022, the entire contents of each of which are incorporated herein by reference.

### BACKGROUND

### 1. Field

The present disclosure is related to a semiconductor device and a semiconductor module.

### 2. Description of Related Art

A discrete semiconductor device that includes a GaN transistor is known (refer to, for example, Japanese Laid-Open Patent Publication No. 2017-37967).

### BRIEF DESCRIPTION OF DRAWINGS

FIG. 1 is a schematic plan view showing a first embodiment of a semiconductor device.

FIG. 2 is a schematic cross-sectional view showing part of the semiconductor device taken along line F2-F2 in FIG. 1.

FIG. 3 is a schematic cross-sectional view showing the semiconductor device taken along line F3-F3 in FIG. 1.

FIG. 4 is a schematic enlarged plan view showing part of the semiconductor device of FIG. 1 including an active clamp circuit.

FIG. 5 is a schematic cross-sectional view showing part of the semiconductor device taken along line F5-F5 in FIG. 1.

FIG. 6 is a circuit diagram of the semiconductor device shown in FIG. 1.

FIG. 7 is a schematic plan view showing a semiconductor module in the first embodiment.

FIG. 8 is a schematic cross-sectional view showing the semiconductor module taken along line F8-F8 in FIG. 7.

FIG. 9 is a graph showing changes in drain-source voltage and gate-source voltage of a GaN transistor and gate-source voltage of a clamp transistor of the active clamp circuit.

FIG. 10 is a schematic plan view showing the internal structure of a semiconductor module in a second embodiment.

FIG. 11 is a schematic plan view mainly showing the interconnect structure of the semiconductor module shown in FIG. 10.

FIG. 12 is a schematic plan view showing the semiconductor module.

FIG. 13 is a schematic cross-sectional view showing the semiconductor module taken along line F13-F13 in FIG. 12.

FIG. 14 is a schematic cross-sectional view showing the semiconductor module taken along line F14-F14 in FIG. 12.

FIG. 15 is a circuit diagram of the semiconductor module shown in FIG. 12.

FIG. 16 is a schematic cross-sectional view showing a pull-down resistor of an active clamp circuit in a modified example of a semiconductor device.

FIG. 17 is a schematic cross-sectional view showing a pull-down resistor in a modified example of a semiconductor device.

FIG. 18 is a circuit diagram of a semiconductor device in a modified example.

FIG. 19 is a schematic enlarged plan view showing part of the semiconductor device of FIG. 18 including an active clamp circuit.

FIG. 20 is a circuit diagram of a semiconductor device in a modified example.

FIG. 21 is a schematic enlarged plan view showing part of the semiconductor device of FIG. 20 including an active clamp circuit.

FIG. 22 is a circuit diagram of a semiconductor device in a modified example.

FIG. 23 is a schematic enlarged plan view showing part of the semiconductor device of FIG. 22 including an active clamp circuit.

FIG. 24 is a schematic plan view showing a semiconductor module of a modified example.

### DETAILED DESCRIPTION

Embodiments of a semiconductor device and a semiconductor module of the present disclosure will be described below with reference to the drawings. In the drawings, components may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### First Embodiment

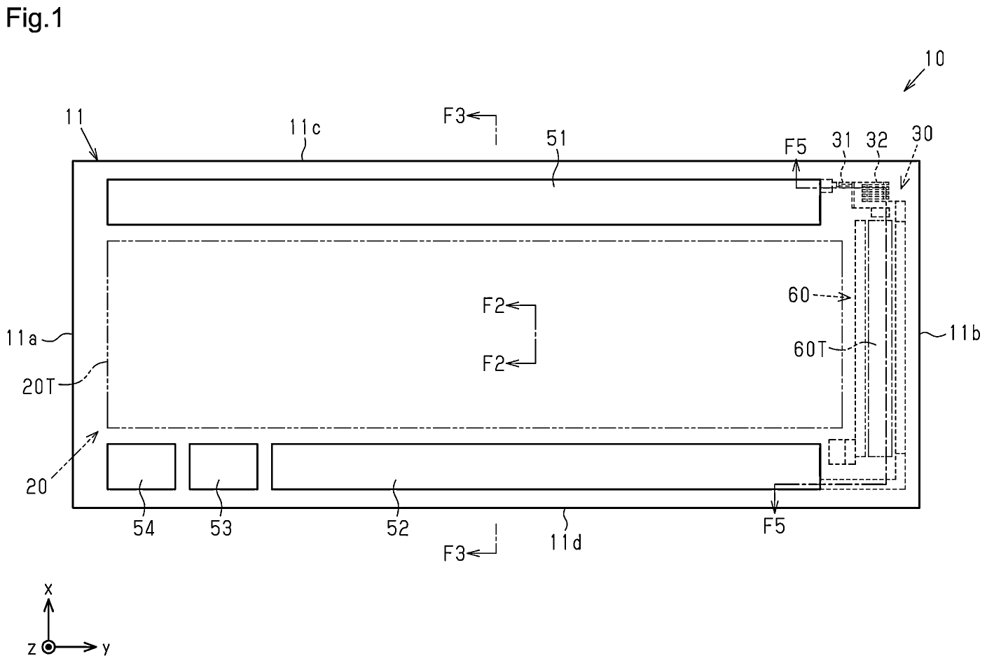

With reference to FIGS. 1 to 8, the configurations of a semiconductor device and a semiconductor module in a first embodiment will now be described. FIG. 1 schematically shows the planar structure of the semiconductor device.

### General Configuration of Semiconductor Device

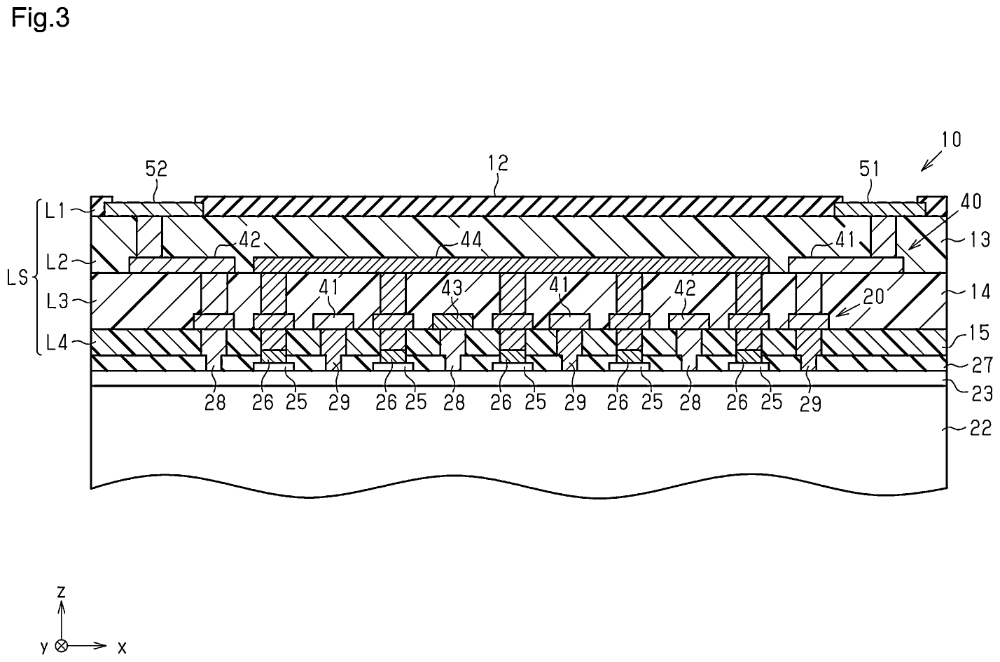

As shown in FIG. 1, a semiconductor device 10 includes a semiconductor substrate 11, a GaN transistor 20, and an active clamp circuit 30 electrically connected to the GaN transistor 20. The GaN transistor 20 and the active clamp circuit 30 are formed on the semiconductor substrate 11. The GaN transistor 20 and the active clamp circuit 30 are connected by an interconnect layer 40 (refer to FIG. 3) formed on the semiconductor substrate 11. Thus, the semiconductor device 10 is a semiconductor chip that includes both the GaN transistor 20 and the active clamp circuit 30.

In the description hereafter, the thickness-wise direction of the semiconductor substrate 11 refers to the z-direction. Two directions that are orthogonal to each other and the z-direction refer to the x-direction and the y-direction. A view of the semiconductor device 10 taken in the z-direction will be referred to as a plan view.

The semiconductor substrate 11 has the form of a rectangular plate having a long-side direction and a short-side direction in plan view. In the present embodiment, the short-side direction of the semiconductor substrate 11 is aligned with the x-direction, and the long-side direction of the semiconductor substrate 11 is aligned with the y-direction. The semiconductor substrate 11 may be formed from silicon (Si), silicon carbide (SiC), gallium nitride (GaN), sapphire, or other substrate materials. In an example, the semiconductor substrate 11 may be a Si substrate. The semiconductor substrate 11 may have a thickness, for example, in a range of 200 μm to 1500 μm. The dimension of the semiconductor substrate 11 in the long-side direction (dimension in the y-direction) is, for example, 2 mm. The dimension of the semiconductor substrate 11 in the short-side direction (dimension in the x-direction) is, for example, 4 mm.

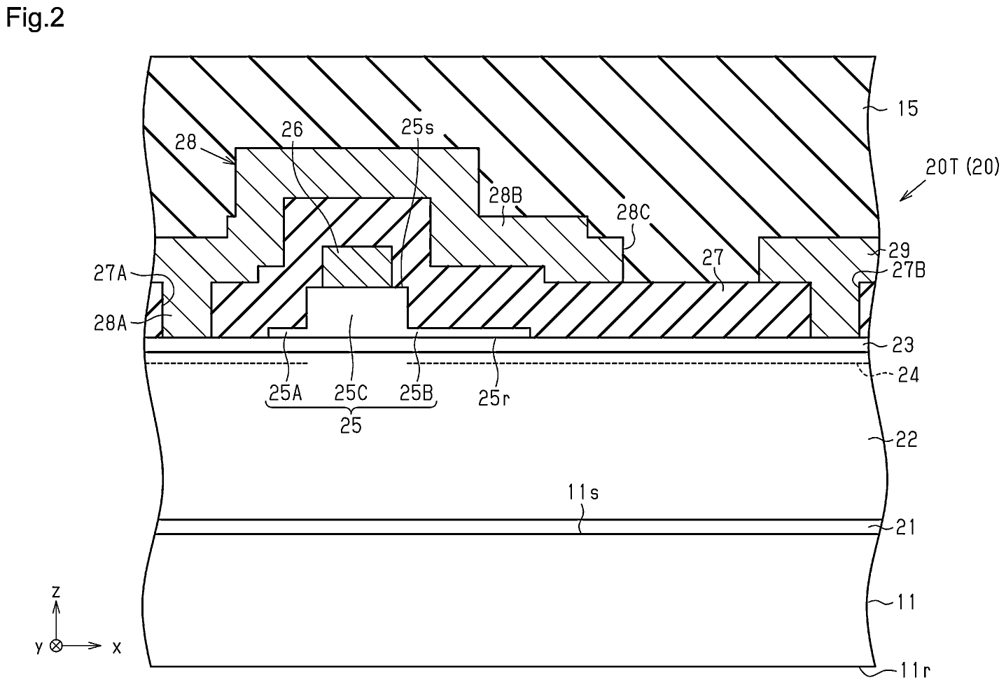

The semiconductor substrate 11 includes a substrate front surface 11s and a substrate back surface 11r (refer to FIG. 2) that face opposite directions in the z-direction. The semiconductor substrate 11 includes a first side surface 11a and a second side surface 11b, which are side surfaces located at opposite ends in the long-side direction (y-direction), and a third side surface 11c and a fourth side surface 11d, which are side surfaces located at opposite ends in the short-side direction (x-direction).

The GaN transistor 20 and the active clamp circuit 30 are arranged next to each other on the semiconductor substrate 11 in the long-side direction of the semiconductor substrate 11 (y-direction). In the present embodiment, the active clamp circuit 30 is located closer to the second side surface 11b than the GaN transistor 20 is.

The GaN transistor 20 is a high-electron-mobility transistor (HEMT) that uses a nitride semiconductor. The GaN transistor 20 includes an active region 20T in which a transistor is formed. In plan view, the active region 20T is rectangular so that the long sides extend in the y-direction and the short sides extend in the x-direction. In the present embodiment, in plan view, the long-side direction of the semiconductor substrate 11 is aligned with the y-direction, and the short-side direction of the semiconductor substrate 11 is aligned with the x-direction. Hence, the long-side direction of the active region 20T is aligned with the long-side direction of the semiconductor substrate 11. The short-side direction of the active region 20T is aligned with the short-side direction of the semiconductor substrate 11.

In plan view, a region of the semiconductor substrate 11 in which the GaN transistor 20 is formed has a first area, and a region of the semiconductor substrate 11 in which the active clamp circuit 30 is formed has a second area. The first area is greater than the second area. In an example, the first area is greater than two times the second area. The first area is greater than three times the second area. The first area is greater than four times the second area. The first area is greater than five times the second area. The first area is less than or equal to six times the second area. The region of the semiconductor substrate 11 in which the GaN transistor 20 is formed is defined by the entirety of the semiconductor substrate 11 in the x-direction in a range of the active region 20T of the GaN transistor 20 in the y-direction in plan view. The region of the semiconductor substrate 11 in which the active clamp circuit 30 is formed is defined by the entirety of the semiconductor substrate 11 in the x-direction between the active region 20T and the second side surface 11b in the y-direction in plan view.

As shown in FIG. 1, the semiconductor device 10 includes a drain pad 51, a main source pad 52, a sense source pad 53, and a gate pad 54, which are electrode pads used as external electrodes. The pads 51 to 54 are formed in the region including the GaN transistor 20 and are exposed to the outside of the semiconductor device 10. The pads 51 to 54 are electrically connected to both the GaN transistor 20 and the active clamp circuit 30 by the interconnect layer 40 (refer to FIG. 3). The pads 51 to 54 may be formed from any conductive material including at least one of, for example, copper (Cu), aluminum (Al), an AlCu alloy, tungsten (W), titanium (Ti), and titanium nitride (TiN).

The GaN transistor 20 shown in FIG. 3 includes a gate electrode 26, a source electrode 28, and a drain electrode 29. As shown in FIGS. 1 and 3, the drain pad 51 is electrically connected to the drain electrode 29 of the GaN transistor 20. The main source pad 52 and the sense source pad 53 are each electrically connected to the source electrode 28 of the GaN transistor 20. In the present embodiment, the main source pad 52 corresponds to a “source pad.” The gate pad 54 is electrically connected to the gate electrode 26 of the GaN transistor 20.

In plan view, the drain pad 51 is located closer to the third side surface 11c than the center, in the x-direction, of the semiconductor substrate 11 is. In the present embodiment, in plan view, the drain pad 51 is located closer to the third side surface 11c than the active region 20T is. The drain pad 51 extends in the y-direction from an end of the semiconductor substrate 11 that is located toward the first side surface 11a to the proximity of the active clamp circuit 30.

In plan view, the main source pad 52, the sense source pad 53, and the gate pad 54 are located closer to the fourth side surface 11d than the center, in the x-direction, of the semiconductor substrate 11 is. In the present embodiment, in plan view, the pads 52 to 54 are located closer to the fourth side surface 11d than the active region 20T is. The pads 52 to 54 are arranged in a line in the y-direction. In the present embodiment, the gate pad 54, the sense source pad 53, and the main source pad 52 are sequentially arranged from the first side surface 11a toward the second side surface 11b. In plan view, the main source pad 52 is greater in area than the sense source pad 53 and the gate pad 54. The shape and arrangement of the pads 51 to 54 may be changed in any manner.

### Detailed Configuration of GaN Transistor and its Surroundings

FIG. 2 is a schematic cross-sectional view of the semiconductor device 10 taken along line F2-F2 in FIG. 1 and showing an example of the cross-sectional structure of the GaN transistor 20. Hatching lines are not shown in certain parts to aid understanding.

As shown in FIG. 2, the GaN transistor 20 is formed on the semiconductor substrate 11. The GaN transistor 20 includes a buffer layer 21 formed on the semiconductor substrate 11, an electron transit layer 22 formed on the buffer layer 21 and including a main drift layer, and an electron supply layer 23 arranged on the electron transit layer 22.

The buffer layer 21 is arranged between the semiconductor substrate 11 and the electron transit layer 22 and is composed of any material that reduces lattice mismatching between the semiconductor substrate 11 and the electron transit layer 22. The buffer layer 21 includes one or more nitride semiconductor layers. The buffer layer 21 may include, for example, at least one of an aluminum nitride (AlN) layer, an aluminum gallium nitride (AlGaN) layer, and a graded AlGaN layer of different aluminum (Al) compositions. For example, the buffer layer 21 may include a single AlN layer, a single AlGaN layer, a layer having a superlattice structure of AlGaN/GaN, a layer having a superlattice structure of AlN/AlGaN, or a layer having a superlattice structure of AlN/GaN.

In an example, the buffer layer 21 includes a first buffer layer that is an AlN layer formed on the semiconductor substrate 11 and a second buffer layer that is an AlGaN layer formed on the AlN layer. In an example, the first buffer layer is an AlN layer having a thickness of 200 nm. In an example, the second buffer layer has a structure in which multiple AlGaN layers are stacked. To inhibit current leakage of the buffer layer 21, the buffer layer 21 may be partially doped with an impurity so that the buffer layer 21 becomes semi-insulating. In this case, the impurity is, for example, carbon (C) or iron (Fe). The concentration of the impurity may be, for example, greater than or equal to 4×10¹⁶ cm⁻³.

The electron transit layer 22 is composed of a nitride semiconductor and may be, for example, a GaN layer. The thickness of the electron transit layer 22 may be, for example, in a range of 300 nm to 2 μm, and more preferably, in a range of 300 nm to 400 nm. In an example, the thickness of the electron transit layer 22 is 350 nm.

To inhibit current leakage of the electron transit layer 22, the electron transit layer 22 may be partially doped with an impurity so that the electron transit layer 22 excluding its surface region becomes semi-insulating. In this case, the impurity is, for example, C. The concentration of the impurity may be, for example, greater than or equal to 1×10¹⁹ cm⁻³ at a peak concentration. More specifically, the electron transit layer 22 may include GaN layers having different impurity concentrations, for example, a C-doped GaN layer and a non-doped GaN layer. The C concentration in the C-doped GaN layer may be in a range of 9×10¹⁸ cm⁻³ to 9×10¹⁹ cm⁻³.

The electron supply layer 23 is composed of a nitride semiconductor having a larger band gap than the electron transit layer 22 and may be, for example, an AlGaN layer. The band gap increases as the Al composition increases. Therefore, the electron supply layer 23, which is an AlGaN layer, has a larger band gap than the electron transit layer 22, which is a GaN layer. In an example, the electron supply layer 23 is composed of Al_{z}Ga_{1-z}N, where 0.1<z<0.4, and more preferably, 0.2<z<0.3. In an example, z=0.25. The electron supply layer 23 has a thickness in a range of, for example, 5 nm to 20 nm. In an example, the electron supply layer 23 has a thickness in a range of 8 nm to 15 nm.

The electron transit layer 22 and the electron supply layer 23 are composed of nitride semiconductors having different lattice constants. A lattice-mismatching junction between the electron transit layer 22 and the electron supply layer 23 imposes strain on the electron supply layer 23. The strain induces a two-dimensional electron gas 24 (2DEG) in the electron transit layer 22. The 2DEG 24 spreads in the electron transit layer 22 at a location close to the heterojunction interface between the electron transit layer 22 and the electron supply layer 23 (for example, approximately a few nanometers away from the interface). The 2DEG 24 is used as a current path (channel) of the GaN transistor 20.

The GaN transistor 20 further includes a gate layer 25 formed on a portion of the electron supply layer 23, the gate electrode 26 formed on the gate layer 25, a passivation layer 27, the source electrode 28, and the drain electrode 29. The passivation layer 27 covers the electron supply layer 23, the gate layer 25, and the gate electrodes 26 and includes a first opening 27A and a second opening 27B. In the present embodiment, the passivation layer 27 corresponds to an “insulation layer formed on a semiconductor substrate.” The source electrode 28 is in contact with the electron supply layer 23 through the first opening 27A. The drain electrode 29 is in contact with the electron supply layer 23 through the second opening 27B.

The gate layer 25 is composed of a nitride semiconductor containing an acceptor impurity. The gate layer 25 is formed from, for example, any material having a smaller band gap than the electron supply layer 23, which is an AlGaN layer. In an example, the gate layer 25 is a GaN layer (p-type GaN layer) doped with an acceptor impurity. The acceptor impurity may contain at least one of zinc (Zn), magnesium (Mg), and carbon (C). The maximum concentration of the acceptor impurity in the gate layer 25 is, for example, in a range of 7×10¹⁸ cm⁻³ to 1×10²⁰ cm⁻³. The GaN transistor 20, which includes the gate layer 25 composed of a nitride semiconductor including an acceptor impurity, depletes the 2DEG 24 in a region immediately below the gate layer 25. This allows the GaN transistor 20 to perform a normally-off operation. That is, the GaN transistor 20 is a normally-off transistor.

The gate layer 25 includes a bottom surface 25r in contact with the electron supply layer 23 and an upper surface 25s opposite to the bottom surface 25r. The gate electrode 26 is formed on the upper surface 25s of the gate layer 25.

In the present embodiment, the gate layer 25 includes a ridge 25C including the upper surface 25s, on which the gate electrode 26 is formed, and two extensions (first extension 25A and second extension 25B) extending outward from the ridge 25C. in plan view.

In plan view, the first extension 25A extends from the ridge 25C toward the first opening 27A. The first extension 25A is separate from the first opening 27A.

In plan view, the second extension 25B extends from the ridge 25C toward the second opening 27B. The second extension 25B is separate from the second opening 27B.

The ridge 25C is located between the first extension 25A and the second extension 25B and is formed integrally with the first extension 25A and the second extension 25B. Since the gate layer 25 includes the first extension 25A and the second extension 25B, the bottom surface 25r is greater in area than the upper surface 25s. In the present embodiment, the second extension 25B extends longer than the first extension 25A outward from the ridge 25C in plan view.

The ridge 25C corresponds to a relatively thick portion of the gate layer 25 and has a thickness in a range of, for example, 80 nm to 150 nm. The thickness of the gate layer 25, particularly, the ridge 25C, may be determined taking into consideration parameters including the gate threshold voltage. In an example, the thickness of the gate layer 25 (ridge 25C) is greater than 110 nm.

Each of the first extension 25A and the second extension 25B is smaller in thickness than the ridge 25C. In an example, the thickness of each of the first extension 25A and the second extension 25B is less than or equal to one-half of the thickness of the ridge 25C.

In the present embodiment, each of the extensions 25A and 25B is a flat portion having a substantially constant thickness. In this specification, “substantially constant thickness” refers to a thickness being within a manufacturing variation range (for example, 20%). Alternatively, each of the extensions 25A and 25B may include a tapered portion having a thickness that gradually decreases as the ridge 25C becomes farther away in a region abutting the ridge 25C. Each of the extensions 25A and 25B may include a flat portion having a substantially constant thickness in a region located away from the ridge 25C by a predetermined distance. In an example, the flat portion has a thickness in a range of 5 nm to 25 nm.

The gate electrode 26 formed on the ridge 25C is composed of one or more metal layers. In an example, the metal layer includes a TiN layer. Alternatively, the gate electrode 26 may include a first metal layer formed of Ti and a second metal layer formed on the first metal layer and formed of TiN. The gate electrode 26 has a thickness in a range of, for example, 50 nm to 200 nm. The gate electrode 26 may form a Schottky junction with the gate layer 25.

The first opening 27A and the second opening 27B of the passivation layer 27 are separate from the gate layer 25. The gate layer 25 is arranged between the first opening 27A and the second opening 27B. More specifically, the gate layer 25 is arranged between the first opening 27A and the second opening 27B at a position closer to the first opening 27A than to the second opening 27B. The passivation layer 27 extends along the upper surface of the electron supply layer 23, the side surface and the upper surface 25s of the gate layer 25, and the side surface and the upper surface of the gate electrode 26. Thus, the passivation layer 27 includes a non-flat surface.

The source electrode 28 and the drain electrode 29 are formed of one or more metal layers. The metal layer may include any combination of, for example, a Ti layer, a TiN layer, an Al layer, an AlSiCu layer, and an AlCu layer. At least a portion of the source electrode 28 fills the first opening 27A. At least a portion of the drain electrode 29 fills the second opening 27B. The source electrode 28 is in ohmic contact with the 2DEG 24 present immediately below the electron supply layer 23 through the first opening 27A. The drain electrode 29 is in ohmic contact with the 2DEG 24 present immediately below the electron supply layer 23 through the second opening 27B.

The source electrode 28 includes a source contact 28A filling the first opening 27A and a source field plate 28B covering the passivation layer 27. The source field plate 28B is formed integrally with the source contact 28A. In plan view, the source field plate 28B includes an end 28C located between the second opening 27B and the gate layer 25 in plan view. The source field plate 28B extends from the source contact 28A to the end 28C along the surface of the passivation layer 27 toward the drain electrode 29 but is spaced apart from the drain electrode 29. Since the source field plate 28B extends along the non-flat surface of the passivation layer 27, the source field plate 28B includes a non-flat surface in the same manner. In a state in which no gate voltage is applied to the gate electrode 26, that is, in the zero bias state, when a drain voltage is applied to the drain electrode 29, the source field plate 28B lessens the concentration of electric field in the vicinity of the end of the gate electrode 26.

FIG. 3 is a schematic enlarged cross-sectional view of the semiconductor device 10 taken along line F3-F3 in FIG. 1 mainly showing the interconnect layer 40 and its surroundings in the cross-sectional structure of the semiconductor device 10. FIG. 3 mainly shows the connection relationship of the interconnect layer 40. The cross-sectional structure of the GaN transistor 20 is simplified as compared to the cross-sectional structure of the GaN transistor 20 shown in FIG. 2.

As shown in FIG. 3, the interconnect layer 40 and the pads 51 to 54 (refer to FIG. 1) are formed on the GaN transistor 20. The GaN transistor 20 includes a multilayer interconnect structure LS. In an example, the multilayer interconnect structure LS includes a first interconnect layer L1, a second interconnect layer L2, a third interconnect layer L3, and a fourth interconnect layer L4, sequentially arranged from above. In another example, the multilayer interconnect structure LS may further include one or more interconnect layers below the fourth interconnect layer L4. In the present embodiment, the first interconnect layer L1 corresponds to a “front interconnect layer.” The second interconnect layer L2 and the third interconnect layer L3 correspond to an “intermediate interconnect layer.” The fourth interconnect layer L4 corresponds to a “substrate-side interconnect layer.”

The second interconnect layer L2, the third interconnect layer L3, and the fourth interconnect layer L4 may be located closer to the semiconductor substrate 11 (refer to FIG. 2) than the first interconnect layer L1 is. The fourth interconnect layer L4 and the first interconnect layer L1 are located at opposite sides of the second interconnect layer L2 and the third interconnect layer L3.

The first to third interconnect layers L1 to L3 are formed on the GaN transistor 20. The fourth interconnect layer L4 is aligned with the GaN transistor 20 in the z-direction. In other words, the GaN transistor 20 is formed in the fourth interconnect layer L4.

The semiconductor device 10 further includes a first insulation layer 12 covering the first interconnect layer L1, a second insulation layer 13 covering the second interconnect layer L2, a third insulation layer 14 covering the third interconnect layer L3, and a fourth interconnect layer 15 arranged between the third interconnect layer L3 and the fourth interconnect layer L4. The insulation layers 12 to 15 are formed from, for example, a material including silicon oxide (SiO₂), silicon nitride (SiN), or the like.

The drain pad 51, the main source pad 52, the sense source pad 53, and the gate pad 54 (refer to FIG. 1) are formed in the first interconnect layer L1, which is the uppermost layer in the multilayer interconnect structure LS. The pads 51 to 54 are insulated from each other by the first insulation layer 12. The pads 51 to 54 may be at least partially covered by the first insulation layer 12. The first insulation layer 12 may include openings that partially expose the upper surface of the pads 51 to 54.

The interconnect layer 40 includes a drain interconnect 41, a main source interconnect 42, a sense source interconnect 43, and a gate interconnect 44. The drain interconnect 41 is configured to electrically connect the drain pad 51 and the drain electrode 29 of the GaN transistor 20. The main source interconnect 42 is configured to electrically connect the main source pad 52 and the source electrode 28 of the GaN transistor 20. The sense source interconnect 43 is configured to electrically connect the sense source pad 53 (refer to FIG. 1) and the source electrode 28 of the GaN transistor 20. The gate interconnect 44 is configured to electrically connect the gate pad 54 (refer to FIG. 1) and the gate electrode 26 of the GaN transistor 20.

The interconnects 41 to 44 are formed in the second interconnect layer L2 and the third interconnect layer L3. The interconnects 41 to 44 are insulated from each other by the second insulation layer 13 and the third insulation layer 14. The interconnects 41 to 44 each include a first interconnect part formed in the second interconnect layer L2, a first via extending in the second insulation layer 13 in the z-direction, a second interconnect part formed in the third interconnect layer L3, and a second via extending in the third interconnect layer L3 in the z-direction. The first via is arranged on the first interconnect part and is exposed from the first interconnect layer L1. Thus, the first vias of the interconnects 41 to 44 respectively connect the pads 51 to 54 to the first interconnect parts corresponding to the interconnects 41 to 44. The second via is arranged on the second interconnect part and is connected to the first interconnect part. In other words, the second via connects the first interconnect part and the second interconnect part. The second vias of the interconnects 41 to 44 are connected to the electrodes 26, 28, and 29 corresponding to the interconnects 41 to 44. In the same manner as the pads 51 to 54, the interconnects 41 to 44 may be formed from, for example, any conductive material including at least one of Cu, Al, an AlCu alloy, W, Ti, and TiN.

### Detailed Configuration of Active Clamp Circuit and its Surroundings

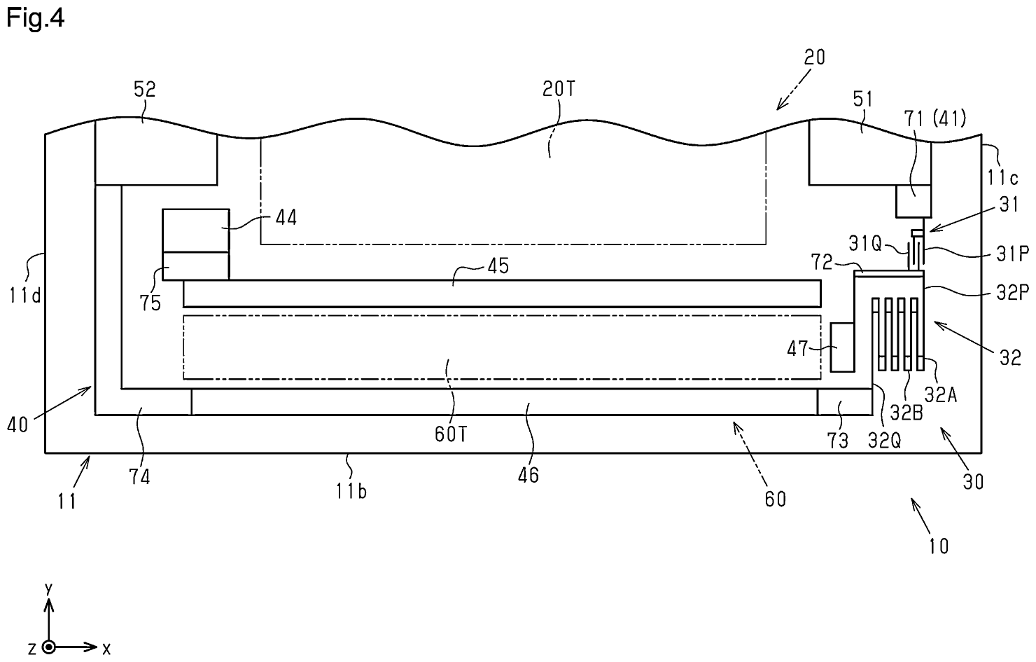

FIG. 4 is an enlarged view of the active clamp circuit 30 shown in FIG. 1 and its surroundings. To facilitate illustration, FIG. 4 shows wiring of the active clamp circuit 30 with solid lines.

As shown in FIG. 4, the active clamp circuit 30 includes a clamp transistor 60, a clamp capacitor 31, and a pull-down resistor 32. The active clamp circuit 30 is electrically connected to the GaN transistor 20.

The clamp transistor 60 is electrically connected to the GaN transistor 20. The GaN transistor 20 and the clamp transistor 60 are formed next to each other in the long-side direction of the semiconductor substrate 11 (y-direction). The clamp transistor 60 is located closer to the second side surface 11b than the GaN transistor 20 is in the y-direction. The clamp transistor 60 includes an active region 60T in which a transistor is formed. In plan view, the active region 60T is rectangular and has a long-side direction and a short-side direction. In the present embodiment, the active region 60T is rectangular so that the long-side direction is aligned with the x-direction and the short-side direction is aligned with the y-direction. Since the long-side direction of the semiconductor substrate 11 is aligned with the y-direction and the short-side direction of the semiconductor substrate 11 is aligned with the x-direction in plan view, the long-side direction of the active region 60T is orthogonal to the long-side direction of the semiconductor substrate 11. Thus, the long-side direction of the active region 60T is orthogonal to the long-side direction of the active region 20T of the GaN transistor 20. In the present embodiment, the dimension of the active region 60T in the x-direction is larger than the dimension of the active region 20T of the GaN transistor 20 in the x-direction. The dimensions of the active region 60T in the x-direction and the y-direction may be changed in any manner.

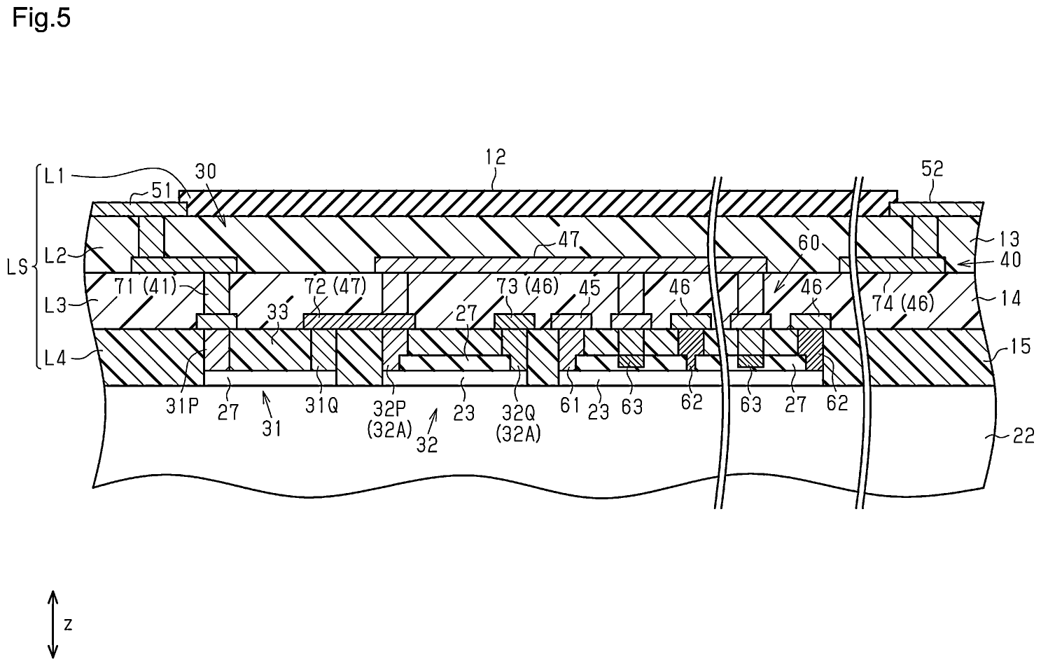

FIG. 5 is a schematic cross-sectional structure of the clamp transistor 60, the clamp capacitor 31, and the pull-down resistor 32 obtained by cutting the semiconductor device 10 along line F5-F5 in FIG. 1. FIG. 5 mainly shows the positions of the clamp transistor 60, the clamp capacitor 31, and the pull-down resistor 32 in the z-direction and the connection relationships of the clamp transistor 60, the clamp capacitor 31, and the pull-down resistor 32. Thus, the cross-sectional structure of the clamp transistor 60 is shown in a simplified manner as compared to the cross-sectional structure of the GaN transistor 20 shown in FIG. 2. Also, in FIG. 5, the cross-sectional structure of the pull-down resistor 32 is shown in a simplified manner as compared to the cross-sectional structure of the actual pull-down resistor 32 obtained by cutting along line F5-F5 in FIG. 1.

As shown in FIG. 5, the clamp transistor 60 is configured in the same manner as the GaN transistor 20. The clamp transistor 60 includes the buffer layer 21 (refer to FIG. 2), the electron transit layer 22, the electron supply layer 23, and the passivation layer 27. Thus, in other words, the clamp transistor 60 includes a sub drift layer (electron transit layer 22) composed of the same material as the electron transit layer 22 composing a main drift layer of the GaN transistor 20.

The passivation layer 27 includes a third opening and a fourth opening exposing the electron supply layer 23. Although not shown, the clamp transistor 60 includes the gate layer 25 formed on the electron supply layer 23. The third opening and the fourth opening of the passivation layer 27 are separated from the gate layer 25 of the clamp transistor 60. The gate layer 25 is arranged between the third opening and the fourth opening. The clamp transistor 60, which includes the gate layer 25 composed of a nitride semiconductor including an acceptor impurity, performs a normally-off operation in the same manner as the GaN transistor 20. That is, the clamp transistor 60 is a normally-off transistor.

The clamp transistor 60 is aligned with the GaN transistor 20 (refer to FIG. 1) in the z-direction. The clamp transistor 60 is formed in the fourth interconnect layer L4. In other words, the clamp transistor 60 is formed on the semiconductor substrate 11. This allows the clamp transistor 60 and the GaN transistor 20 to be simultaneously manufactured in the same manufacturing steps.

The clamp transistor 60 includes a drain electrode 61, a source electrode 62, and a gate electrode 63. The electrodes 61 to 63 are formed from, for example, the same material as the material forming the gate electrode 26, the source electrode 28, and the drain electrode 29 of the GaN transistor 20.

At least a portion of the source electrode 62 fills the third opening. The source electrode 62 is in ohmic contact with the 2DEG 24 (refer to FIG. 2) present immediately below the electron supply layer 23 through the third opening. At least a portion of the drain electrode 61 fills the fourth opening. The drain electrode 61 is in ohmic contact with the 2DEG 24 present immediately below the electron supply layer 23 through the fourth opening. The drain electrode 61 and the source electrode 62 are separated from each other.

The gate electrode 63 is arranged between the drain electrode 61 and the source electrode 62. Although not shown, the gate electrode 63 is formed on the gate layer 25 (refer to FIG. 2). The gate electrode 63 is covered by the passivation layer 27.

In the present embodiment, the shapes and arrangement of the drain electrode 61, the source electrode 62, and the gate electrode 63 are the same as those of the drain electrode 29, the source electrode 28, and the gate electrode 26 of the GaN transistor 20. The shapes and arrangement of the drain electrode 61, the source electrode 62, and the gate electrode 63 may be changed in any manner and, for example, may differ from those of the drain electrode 29, the source electrode 28, and the gate electrode 26 of the GaN transistor 20.

As shown in FIG. 4, in plan view, the clamp capacitor 31 and the pull-down resistor 32 are formed in a region of the semiconductor substrate 11 differing from where the GaN transistor 20 and the clamp transistor 60 are formed. More specifically, in plan view, the clamp capacitor 31 and the pull-down resistor 32 are formed in a region closer to the third side surface 11c than the clamp transistor 60 is in the x-direction and closer to the second side surface 11b than the drain pad 51 is in the y-direction. As viewed in the long-side direction of the active region 20T of the GaN transistor 20 (y-direction), the clamp capacitor 31 and the pull-down resistor 32 are arranged to overlap the drain pad 51 in the short-side direction of the active region 20T of the GaN transistor 20 (x-direction). In the present embodiment, in plan view, the clamp capacitor 31 and the pull-down resistor 32 are arranged next to each other in the y-direction. In plan view, the clamp capacitor 31 is located closer to the drain pad 51 than the pull-down resistor 32 is. In plan view, the pull-down resistor 32 and the clamp transistor 60 are located at the same position in the y-direction. Therefore, the clamp capacitor 31 is located closer to the GaN transistor 20 than the clamp transistor 60 is in the y-direction.

As shown in FIG. 4, the clamp capacitor 31 includes a first electrode 31P and a second electrode 31Q. Each of the first electrode 31P and the second electrode 31Q includes multiple wires.

The first electrode 31P includes multiple first wires (in the present embodiment, two) extending in the y-direction and a second wire extending in the x-direction. The two first wires are spaced apart from each other in the x-direction. The second wire connects ends of the two first wires located closer to the first side surface 11a (refer to FIG. 1) in the x-direction.

The second electrode 31Q includes multiple third wires (in the present embodiment, two) extending in the y-direction and a fourth wire extending in the x-direction. The two third wires are spaced apart from each other in the x-direction. The third wires are opposed to the first wires of the first electrode 31P in the x-direction. The first wires and the third wires are alternately arranged in the x-direction. The fourth wire is located closer to the second side surface 11b than the second wire of the first electrode 31P is in the y-direction. The fourth wire connects ends of the two third wires located closer to the second side surface 11b in the x-direction.

As shown in FIG. 5, the clamp capacitor 31 is formed on the passivation layer 27. More specifically, the first electrode 31P and the second electrode 31Q of the clamp capacitor 31 are formed on the passivation layer 27. The clamp capacitor 31 is formed in the fourth interconnect layer L4. In other words, the clamp capacitor 31 is aligned with the clamp transistor 60 and the GaN transistor 20 in the z-direction. The electron supply layer 23 is not formed in the region where the clamp capacitor 31 is formed. That is, the passivation layer 27 is formed on the electron transit layer 22. Thus, the clamp capacitor 31 is electrically insulated from the electron transit layer 22 by the passivation layer 27.

An insulation layer 33 is formed on the passivation layer 27. The insulation layer 33 is formed from a material including, for example, SiO₂. The insulation layer 33 is located between the first electrode 31P and the second electrode 31Q. The insulation layer 33 is sandwiched between the first electrode 31P and the second electrode 31Q. More specifically, the insulation layer 33 is located between the first wires of the first electrode 31P and the third wires of the second electrode 31Q in the x-direction. The insulation layer 33 has a thickness of, for example, approximately 1 μm. The insulation layer 33 corresponds to a “dielectric layer.”

As shown in FIG. 4, the pull-down resistor 32 includes a serpentine connection path 32A. In the present embodiment, the connection path 32A is formed of the 2DEG 24 (refer to FIG. 2). In other words, the 2DEG 24 of the pull-down resistor 32 is formed in a serpentine manner in plan view. Thus, the connection path 32A includes a serpentine portion 32B formed in a serpentine manner. Thus, the pull-down resistor 32 includes a resistance component of the serpentine portion 32B. The resistance component of the serpentine portion 32B is set in accordance with the length and width of the serpentine portion 32B. The length and width of the serpentine portion 32B are each set in accordance with, for example, a desired resistance of the pull-down resistor 32.

The pull-down resistor 32 includes a first terminal 32P and a second terminal 32Q forming two ends of the connection path 32A. The first terminal 32P is electrically connected to an end of the serpentine portion 32B located toward the clamp capacitor 31. The second terminal 32Q is electrically connected to an end of the serpentine portion 32B located toward the clamp transistor 60. The first terminal 32P and the second terminal 32Q are electrically connected to each other by the connection path 32A.

As shown in FIG. 5, the first terminal 32P and the second terminal 32Q of the pull-down resistor 32 are arranged on the electron supply layer 23. More specifically, the first terminal 32P and the second terminal 32Q are formed on the electron supply layer 23 and are in ohmic contact with the 2DEG 24 (refer to FIG. 2) present immediately below the electron supply layer 23.

The wiring configuration of the active clamp circuit 30 and its surroundings will now be described.

As shown in FIGS. 4 and 5, the interconnect layer 40 includes a clamp drain interconnect 45, a clamp source interconnect 46, and a clamp gate interconnect 47.

The clamp drain interconnect 45 is electrically connected to multiple drain electrodes 61 of the clamp transistor 60. The clamp drain interconnect 45 is formed in the third interconnect layer L3. For the sake of convenience, in FIGS. 1 and 4, the clamp drain interconnect 45 is located closer to the first side surface 11a of the semiconductor substrate 11 than the active region 60T is. The clamp drain interconnect 45 has the form of a strip elongated in the x-direction. The shown clamp drain interconnect 45 is a portion that joins multiple clamp drain interconnects 45 (refer to FIG. 5) formed on the active region 60T.

The clamp source interconnect 46 is electrically connected to multiple source electrodes 62 of the clamp transistor 60. The clamp source interconnect 46 is formed in the third interconnect layer L3. For the sake of convenience, in FIGS. 1 and 4, the clamp source interconnect 46 is located closer to the second side surface 11b of the semiconductor substrate 11 than the active region 60T is. In plan view, the clamp source interconnect 46 has the form of a strip elongated in the x-direction. The shown clamp source interconnect 46 is a portion that joins multiple clamp source interconnects 46 (refer to FIG. 5) formed on the active region 60T.

The clamp gate interconnect 47 is electrically connected to multiple gate electrodes 63 of the clamp transistor 60. The clamp gate interconnect 47 is formed in the second interconnect layer L2 and the third interconnect layer L3. For the sake of convenience, in FIGS. 1 and 4, the clamp gate interconnect 47 has the form of a small rectangle located next to the active region 60T in the x-direction. However, the actual clamp gate interconnect 47 is formed in the entire active region 60T.

As shown in FIGS. 4 and 5, the interconnect layer 40 further includes a first interconnect 71, a second interconnect 72, a third interconnect 73, a fourth interconnect 74, and a fifth interconnect 75. The first interconnect 71, the second interconnect 72, the third interconnect 73, the fourth interconnect 74, and the fifth interconnect 75 are formed on the semiconductor substrate 11 (refer to FIG. 2). In plan view, the first interconnect 71, the second interconnect 72, the third interconnect 73, the fourth interconnect 74, and the fifth interconnect 75 are formed on a region of the semiconductor substrate 11 located in the long-side direction (y-direction) closer to the clamp transistor 60 than the center, in the long-side direction, of the semiconductor substrate 11 is. The interconnects 71 to 75 are arranged to overlap a region in which the active clamp circuit 30 is formed in plan view. In the present embodiment, the interconnects 71 to 75 are formed closer to the second side surface 11b than the drain pad 51 or the main source pad 52 is in the long-side direction of the semiconductor substrate 11 (y-direction).

The first interconnect 71 electrically connects the clamp capacitor 31 and the drain electrode 29 (refer to FIG. 2) of the GaN transistor 20. More specifically, the first interconnect 71 connects the second wire of the first electrode 31P in the clamp capacitor 31 and one of two ends of the drain pad 51 in the y-direction located closer to the clamp capacitor 31. Since the drain pad 51 is electrically connected to the drain electrode 29 of the GaN transistor 20, the first interconnect 71 is electrically connected to the drain electrode 29. The first interconnect 71 may be formed integrally with the drain interconnect 41. In other words, the drain interconnect 41 may include the first interconnect 71.

As shown in FIG. 4, the first interconnect 71 is formed between the clamp capacitor 31 and the drain pad 51 in the y-direction. In plan view, the first interconnect 71 is formed closer to the third side surface 11c of the semiconductor substrate 11 than the active region 60T of the clamp transistor 60 is. As shown in FIG. 5, the first interconnect 71 is formed in the second interconnect layer L2 and the third interconnect layer L3.

The second interconnect 72 electrically connects the second electrode 31Q of the clamp capacitor 31, the first terminal 32P of the pull-down resistor 32, and the gate electrode 63 of the clamp transistor 60. More specifically, the second interconnect 72 electrically connects the fourth wire of the second electrode 31Q in the clamp capacitor 31 and the first terminal 32P of the pull-down resistor 32 to the gate electrode 63. The second interconnect 72 is a portion of the clamp gate interconnect 47 that is connected to the gate electrode 63. That is, the clamp gate interconnect 47 includes the second interconnect 72. As shown in FIG. 5, the second interconnect 72 is formed in the second interconnect layer L2 and the third interconnect layer L3.

As shown in FIG. 4, in plan view, the second interconnect 72 is located closer to the third side surface 11c of the semiconductor substrate 11 than the active region 60T is. The second interconnect 72 is formed between the clamp capacitor 31 and the pull-down resistor 32 in the y-direction. As shown in FIG. 5, the second interconnect 72 is formed in the third interconnect layer L3.

The third interconnect 73 electrically connects the second terminal 32Q of the pull-down resistor 32 and the source electrode 62 of the clamp transistor 60. The third interconnect 73 is a portion of the clamp source interconnect 46 that is connected to the source electrode 62. That is, the clamp source interconnect 46 includes the third interconnect 73. The third interconnect 73 is formed in the third interconnect layer L3.

As shown in FIG. 4, in plan view, the third interconnect 73 is located closer to the second side surface 11b of the semiconductor substrate 11 than the active region 60T is. The third interconnect 73 extends out from the active region 60T toward the third side surface 11c. As shown in FIG. 5, the third interconnect 73 is formed in the third interconnect layer L3.

The fourth interconnect 74 electrically connects the source electrode 62 of the clamp transistor 60 and the source electrode 28 (refer to FIG. 2) of the GaN transistor 20. More specifically, the fourth interconnect 74 connects the clamp source interconnect 46 to one of two ends of the main source pad 52 in the y-direction located closer to the clamp capacitor 31. Since the clamp source interconnect 46 is electrically connected to the source electrode 62 of the clamp transistor 60, the fourth interconnect 74 is electrically connected to the source electrode 62. Since the main source pad 52 is electrically connected to the source electrode 28 of the GaN transistor 20, the fourth interconnect 74 is electrically connected to the source electrode 28. In the present embodiment, the fourth interconnect 74 is integrated with the clamp source interconnect 46. Thus, the fourth interconnect 74 is a portion of the clamp source interconnect 46. That is, the clamp source interconnect 46 includes the fourth interconnect 74.

As shown in FIG. 4, in plan view, the fourth interconnect 74 is located closer to the fourth side surface 11d of the semiconductor substrate 11 than the active region 60T of the clamp transistor 60 is. As shown in FIG. 5, the fourth interconnect 74 is formed in the second interconnect layer L2 and the third interconnect layer L3.

As shown in FIG. 4, the fifth interconnect 75 electrically connects the drain electrode 61 of the clamp transistor 60 and the gate electrode 26 (refer to FIG. 2) of the GaN transistor 20. More specifically, the fifth interconnect 75 electrically connects the clamp drain interconnect 45 and the gate interconnect 44. Since the clamp drain interconnect 45 is electrically connected to the drain electrode 61 of the clamp transistor 60, the fifth interconnect 75 is electrically connected to the drain electrode 61. Since the gate interconnect 44 is electrically connected to the gate electrode 26 of the GaN transistor 20, the fifth interconnect 75 is electrically connected to the gate electrode 26. For the sake of convenience, in FIGS. 1 and 4, the gate interconnect 44 has the form of a small rectangle. However, the actual gate interconnect 44 is formed in the entire active region 20T. In the present embodiment, the fifth interconnect 75 is integrated with the clamp drain interconnect 45 and the gate interconnect 44.

As shown in FIG. 4, the fifth interconnect 75 is formed between the clamp drain interconnect 45 and the main source pad 52 in the y-direction. The fifth interconnect 75 is formed in the third interconnect layer L3 (refer to FIG. 5).

The wires of the clamp capacitor 31, the first terminal 32P and the second terminal 32Q of the pull-down resistor 32, and the interconnects 71 to 75 may be formed from any conductive material including at least one of, for example, Cu, Al, an AlCu alloy, W, Ti, and TiN. In an example, the wires of the clamp capacitor 31, the first terminal 32P and the second terminal 32Q of the pull-down resistor 32, and the interconnects 71 to 75 are formed from the same conductive material as the material forming the interconnects 41 to 44.

### Circuit Configuration of Semiconductor Device

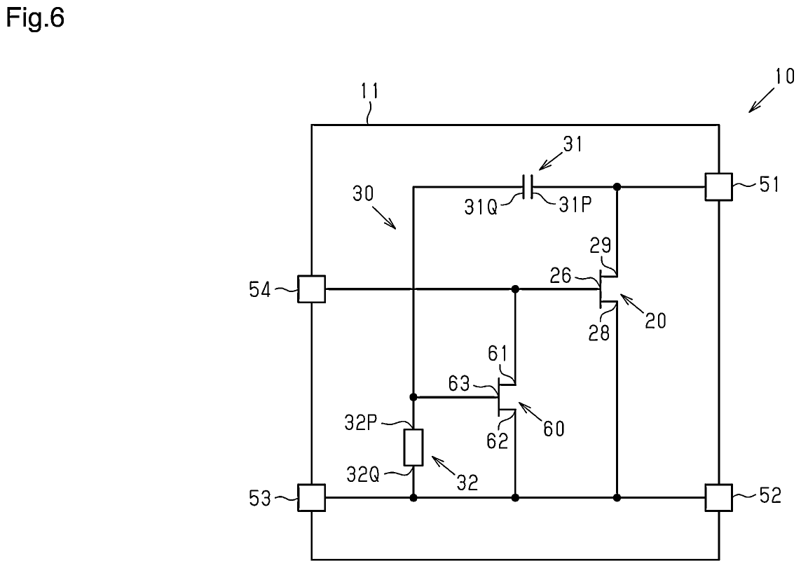

FIG. 6 shows the circuit configuration of the semiconductor device 10. As shown in FIG. 6, the active clamp circuit 30 is connected to the GaN transistor 20. More specifically, the source electrode 62 of the clamp transistor 60 is connected to the source electrode 28 of the GaN transistor 20. The drain electrode 61 of the clamp transistor 60 is connected to the gate electrode 26 of the GaN transistor 20. The clamp capacitor 31 is connected between the drain electrode 29 of the GaN transistor 20 and the gate electrode 63 of the clamp transistor 60. The pull-down resistor 32 is connected between the source electrode 62 and the gate electrode 63 of the clamp transistor 60.

The drain electrode 29 of the GaN transistor 20 and the clamp capacitor 31 are connected to the drain pad 51. The source electrode 28 of the GaN transistor 20, the source electrode 62 of the clamp transistor 60, and the second terminal 32Q of the pull-down resistor 32 are connected to the main source pad 52 and the sense source pad 53. The gate electrode 26 of the GaN transistor 20 and the drain electrode 61 of the clamp transistor 60 are connected to the gate pad 54.

### Configuration of Semiconductor Module

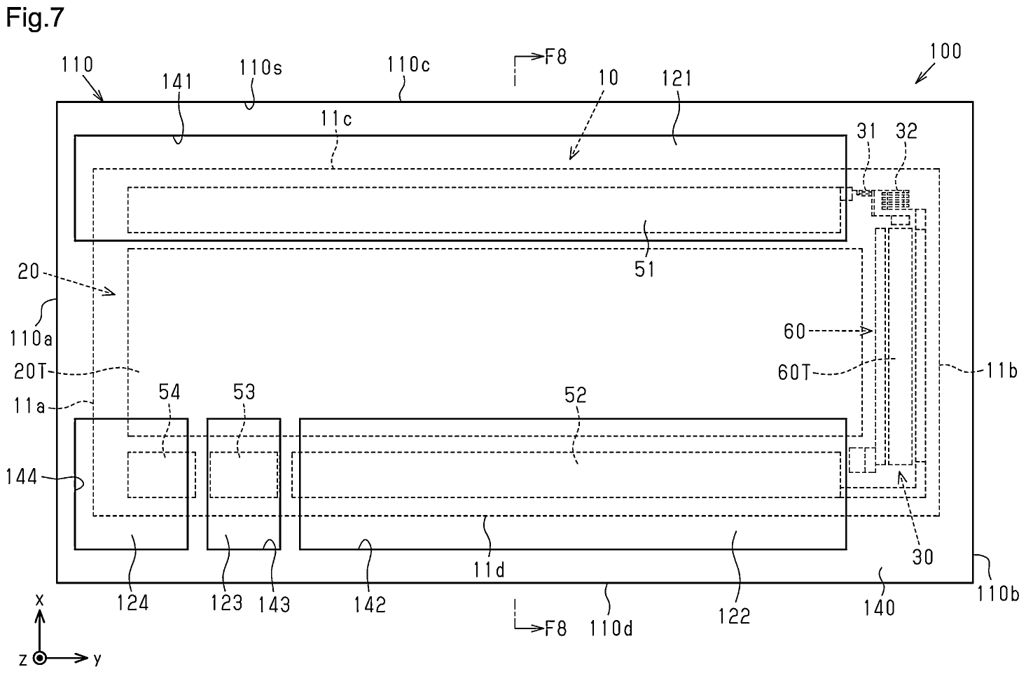

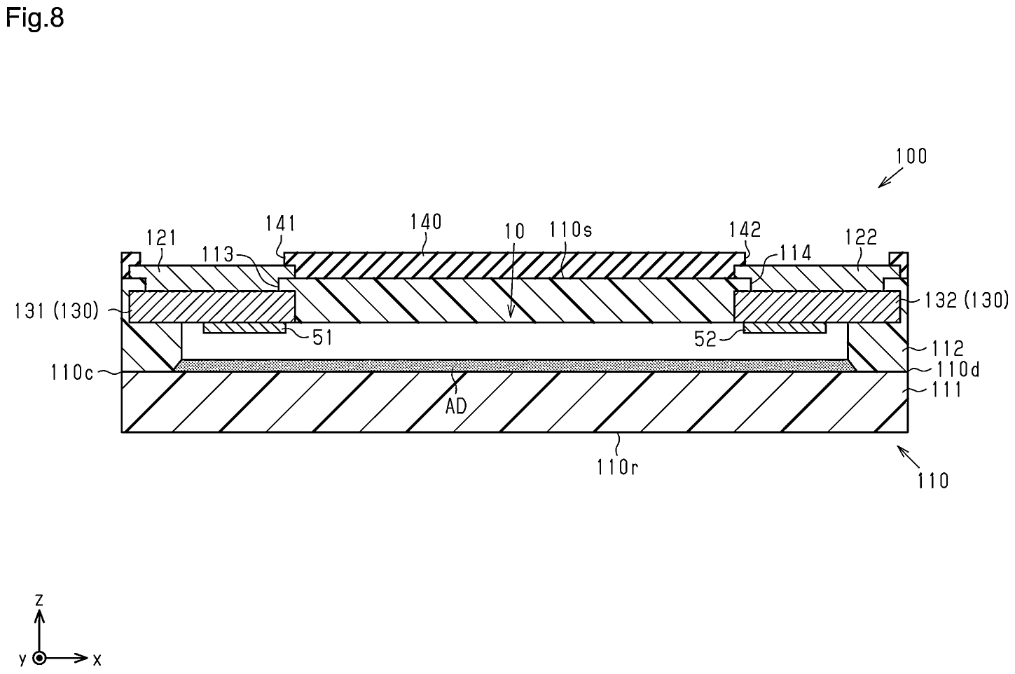

With reference to FIGS. 7 and 8, an example of the structure of a semiconductor module 100 including the semiconductor device 10 will now be described. FIG. 8 is a schematic cross-sectional view of the semiconductor module 100 obtained by cutting the semiconductor module 100 along line F8-F8 in FIG. 7.

As shown in FIGS. 7 and 8, the semiconductor module 100 includes the semiconductor device 10 and an encapsulation resin 110 encapsulating the semiconductor device 10. The encapsulation resin 110 is formed from an insulative resin material. Such a resin material includes, for example, an epoxy resin, an acrylic resin, and a phenol resin. The encapsulation resin 110 defines outer surfaces of the semiconductor module 100. The encapsulation resin 110 includes a resin front surface 110s and a resin back surface 110r, which face opposite directions in the z-direction, and first to fourth resin side surfaces 110a to 110d, each of which is orthogonal to the resin front surface 110s and the resin back surface 110r. The resin front surface 110s faces the same direction as the substrate front surface 11s of the semiconductor substrate 11. The resin back surface 110r faces the same direction as the substrate back surface 11r of the semiconductor substrate 11. The first resin side surface 110a faces the same direction as the first side surface 11a of the semiconductor substrate 11. The second resin side surface 110b faces the same direction as the second side surface 11b of the semiconductor substrate 11. The third resin side surface 110c faces the same direction as the third side surface 11c of the semiconductor substrate 11. The fourth resin side surface 110d faces the same direction as the fourth side surface 11d of the semiconductor substrate 11. As shown in FIG. 7, the encapsulation resin 110 is slightly larger than the semiconductor substrate 11. Thus, in plan view, the semiconductor module 100 has a long-side direction aligned with the long-side direction of the semiconductor substrate 11. The semiconductor module 100 has a short-side direction aligned with the short-side direction of the semiconductor substrate 11.

The semiconductor module 100 includes an insulation layer 140 covering the resin front surface 110s. The insulation layer 140 is formed from, for example, any insulative material including SiO₂ and SiN.

The semiconductor module 100 includes a drain terminal 121, a main source terminal 122, a sense source terminal 123, and a gate terminal 124, which are exposed from the encapsulation resin 110. In the present embodiment, the terminals 121 to 124 are exposed from the resin front surface 110s and each include a portion formed on the resin front surface 110s. The portions of the terminals 121 to 124 formed on the resin front surface 110s are partially covered by the insulation layer 140. More specifically, the insulation layer 140 includes a first opening 141 exposing a portion of the drain terminal 121, a second opening 142 exposing a portion of the main source terminal 122, a third opening 143 exposing a portion of the sense source terminal 123, and a fourth opening 144 exposing a portion of the gate terminal 124. Thus, in the present embodiment, the semiconductor module 100 has a package structure of a surface mount type. The insulation layer 140 may be omitted from the semiconductor module 100.

The drain terminal 121 is electrically connected to the drain electrode 29 (refer to FIG. 2) of the GaN transistor 20. The main source terminal 122 and the sense source terminal 123 are electrically connected to the source electrode 28 (refer to FIG. 2) of the GaN transistor 20. The gate terminal 124 is electrically connected to the gate electrode 26 (refer to FIG. 2) of the GaN transistor 20.

As shown in FIG. 8, the encapsulation resin 110 includes a first encapsulation portion 111 supporting the semiconductor substrate 11 and a second encapsulation portion 112 encapsulating the semiconductor substrate 11 in cooperation with the first encapsulation portion 111. The first encapsulation portion 111 includes the resin back surface 110r. The second encapsulation portion 112 includes the resin front surface 110s. The semiconductor device 10 is bonded to the first encapsulation portion 111 by, for example, a bonding material AD. The bonding material AD may be a conductive bonding material such as solder paste or silver (Ag) paste or may be an insulative bonding material such as an epoxy resin-based adhesive.

The semiconductor module 100 includes interconnects 130 separately connecting the terminals 121 to 124 and the pads 51 to 54. The interconnects 130 are arranged in the encapsulation resin 110. In other words, the encapsulation resin 110 encapsulates the interconnects 130. In an example, the interconnects 130 are arranged between the semiconductor device 10 and the resin front surface 110s in the z-direction. The interconnects 130 are formed of, for example, a metal plate. The configuration of the interconnects 130 may be changed in any manner. In an example, the interconnects 130 may be formed by metal plating. In FIG. 8, the interconnects 130 each have a rectangular cross section. However, the cross-sectional shape of the interconnects 130 may be changed. In an example, the interconnects 130 may be electrically connected to part of each of the pads 51 to 54.

The interconnects 130 include a drain interconnect 131 connecting the drain terminal 121 and the drain pad 51 and a main source interconnect 132 connecting the main source terminal 122 and the main source pad 52. Although not shown, the interconnects 130 include a sense source interconnect connecting the sense source terminal 123 and the sense source pad 53 and a gate interconnect connecting the gate terminal 124 and the gate pad 54.

The encapsulation resin 110 includes a first opening 113 exposing a portion of the drain interconnect 131 and a second opening 114 exposing a portion of the main source interconnect 132. The drain terminal 121 fills the first opening 113 and covers an edge extending around the first opening 113. Thus, the drain terminal 121 is in contact with the drain interconnect 131 and is electrically connected to the drain interconnect 131. The main source terminal 122 fills the second opening 114 and covers an edge extending around the second opening 114. Thus, the main source terminal 122 is in contact with the main source interconnect 132 and is electrically connected to the main source interconnect 132.

Although not shown, the encapsulation resin 110 includes a third opening exposing a portion of the sense source interconnect and a fourth opening exposing a portion of the gate interconnect. The sense source terminal 123 and the gate terminal 124 are formed in the same manner as the drain terminal 121 and the main source terminal 122. The terminals 121 to 124 and the interconnects 130 may be formed from any conductive material including at least one of Cu, Al, an AlCu alloy, W, Ti, and TiN.

### Operation

The operation of the present embodiment will now be described. A semiconductor device that does not include the active clamp circuit 30 is referred to as a “comparative semiconductor device.” The comparative semiconductor device includes only the GaN transistor 20. The GaN transistor 20 is used for, for example, a DC-DC converter.

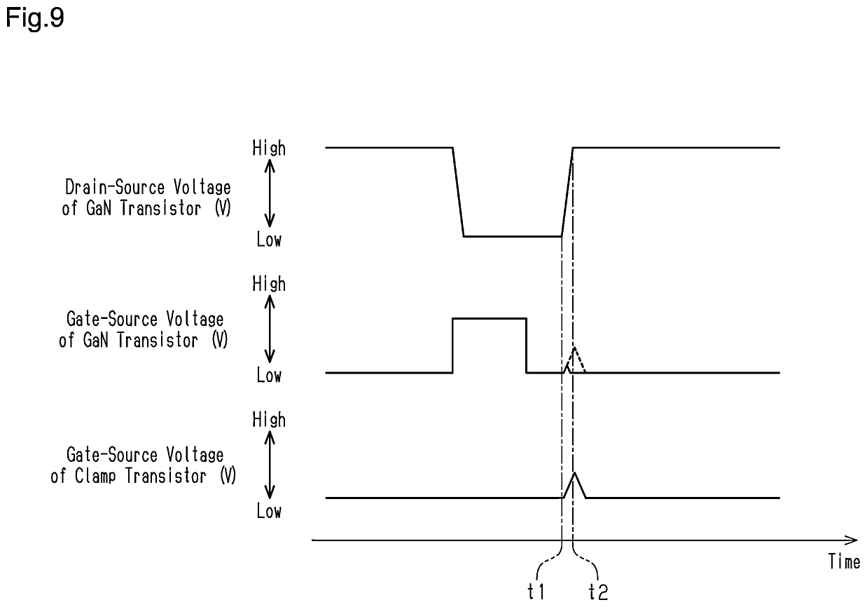

As shown in FIG. 9, in the comparative semiconductor device, while the GaN transistor 20 is turned off, the drain-source voltage of the GaN transistor 20 may change sharply during a period from time t1 to time t2. This occurs, for example, due to an element (e.g., coil of DC-DC converter) that is connected to the GaN transistor 20. At this time, as indicated by the broken lines in the middle section of FIG. 9, the gate-source voltage (gate voltage) of the GaN transistor 20 is increased by gate-drain parasitic capacitance of the GaN transistor 20. When the gate-source voltage exceeds the threshold value of the GaN transistor 20, the GaN transistor 20 will turn on. In other words, in the comparative semiconductor device, even when the GaN transistor 20 is expected to be in a deactivation state, the GaN transistor 20 enters an activation state (erroneous turn-on).

In this regard, in the present embodiment, the clamp transistor 60 is configured to be activated based on a rise of the drain-source voltage of the GaN transistor 20. More specifically, the clamp transistor 60 is configured to be turned on earlier than the GaN transistor 20 in response to a sharp change in the drain-source voltage of the GaN transistor 20. In an example, the capacitance of the clamp capacitor 31 is set so that the voltage of the second electrode 31Q rapidly increases as compared to the gate-source voltage of the GaN transistor 20. For example, the clamp capacitor 31 has a capacitance that is set to be smaller than the gate-drain capacitance of the GaN transistor 20. The clamp transistor 60 may have a threshold voltage that is set to be lower than the threshold voltage of the GaN transistor 20.

When the above-described clamp capacitor 31 is connected to the gate electrode 63 of the clamp transistor 60, the gate-source voltage of the clamp transistor 60 will be increased by a sharp change in the drain-source voltage of the GaN transistor 20. This activates the clamp transistor 60 and allows the gate electrode 26 and the source electrode 28 of the GaN transistor 20 to be connected through the clamp transistor 60. As a result, the gate-source voltage of the GaN transistor 20 shifts from increasing to decreasing before reaching a complete rise. Thus, as indicated by the solid lines in the middle section in FIG. 9, an increase in the gate-source voltage of the GaN transistor 20 is limited. As a result, erroneous turn-on of the GaN transistor 20 is inhibited.

When the comparative semiconductor device is provided with the active clamp circuit 30 as a measure against the erroneous turn-on, the active clamp circuit 30 may be arranged on a circuit substrate arranged outside the comparative semiconductor device. In this case, in the comparative semiconductor device, the GaN transistor 20 is connected to the active clamp circuit 30, arranged on the circuit substrate, by a conductive path such as wires arranged on the circuit substrate. If the conductive path is long, the conductive path has a high parasitic impedance. In addition, the conductive path may have a parasitic inductance that delays activation of the active clamp circuit 30 in response to a sharp change in the drain-source voltage of the GaN transistor 20. Therefore, when the drain-source voltage of the GaN transistor 20 changes sharply, the gate-source voltage may increase, and the GaN transistor 20 may be erroneously turned on.

In contrast, in the present embodiment, both the GaN transistor 20 and the active clamp circuit 30 are formed on the semiconductor substrate 11. This allows the GaN transistor 20 and the active clamp circuit 30 to be electrically connected to each other on the semiconductor substrate 11. In other words, the GaN transistor 20 and the active clamp circuit 30 are electrically connected to each other in the semiconductor device 10. Thus, the conductive path between the GaN transistor 20 and the active clamp circuit 30 is shortened as compared to a structure in which the active clamp circuit 30 is formed on a circuit substrate arranged outside the comparative semiconductor device. This decreases the parasitic impedance and the parasitic inductance of the conductive path. As a result, erroneous turn-on of the GaN transistor 20 is inhibited.

### Advantages

The first embodiment has the following advantages.

(1-1) The semiconductor device 10 includes the semiconductor substrate 11, the GaN transistor 20 formed on the semiconductor substrate 11 and including the drain electrode 29, the source electrode 28, and the gate electrode 26, the active clamp circuit 30 formed on the semiconductor substrate 11 and electrically connected to the GaN transistor 20, the active clamp circuit 30 including the clamp transistor 60 configured to be activated based on a rise of the drain-source voltage of the GaN transistor 20, the drain pad 51 electrically connected to the drain electrode 29 of the GaN transistor 20, the main source pad 52 electrically connected to the source electrode 28 of the GaN transistor 20, and the gate pad 54 electrically connected to the gate electrode 26 of the GaN transistor 20.

With this structure, when the drain-source voltage of the GaN transistor 20 changes sharply, the clamp transistor 60 limits an increase in the gate-source voltage of the GaN transistor 20. Thus, erroneous turn-on of the GaN transistor 20 is inhibited.

The GaN transistor 20 and the active clamp circuit 30 are electrically connected to each other in the semiconductor device 10. Thus, the conductive path between the GaN transistor 20 and the active clamp circuit 30 is shortened. This decreases the parasitic impedance and the parasitic inductance of the conductive path, thereby further inhibiting erroneous turn-on of the GaN transistor 20.

(1-2) The GaN transistor 20 includes the electron transit layer 22 corresponding to a main drift layer. The clamp transistor 60 includes the electron transit layer 22 corresponding to a sub drift layer composed of the same material as the main drift layer.

In this configuration, the GaN transistor 20 and the clamp transistor 60 include the common electron transit layer 22. Thus, the GaN transistor 20 and the clamp transistor 60 are readily formed on the semiconductor substrate 11.

(1-3) The active clamp circuit 30 includes the pull-down resistor 32 connected between the source electrode 62 and the gate electrode 63 of the clamp transistor 60 and the clamp capacitor 31 connected between the drain electrode 29 of the GaN transistor 20 and the gate electrode 63 of the clamp transistor 60.

In this configuration, when the drain-source voltage of the GaN transistor 20 changes sharply, the sharp voltage change increases the gate-source voltage of the clamp transistor 60 and activates the clamp transistor 60. As a result, an increase in the gate-source voltage of the GaN transistor 20 is limited. As described above, activation and deactivation of the clamp transistor 60 is controlled within the semiconductor device 10 instead of being controlled based on a signal from a circuit arranged outside the semiconductor device 10. This eliminates the need to provide the semiconductor device 10 with an additional pad for the signal. Thus, addition of pads for the active clamp circuit 30 on the semiconductor device 10 is limited.

(1-4) As viewed in the z-direction, the GaN transistor 20 and the clamp transistor 60 each include the rectangular active regions 20T and 60T having a long-side direction and a short-side direction. As viewed in the z-direction, the GaN transistor 20 and the clamp transistor 60 are arranged next to each other in the long-side direction of the GaN transistor 20 (y-direction). The long-side direction of the active region 20T of the GaN transistor 20 is orthogonal to the long-side direction of the active region 60T of the clamp transistor 60.

With this structure, the size of the semiconductor substrate 11 in the long-side direction is limited as compared to a structure in which the long-side direction of the active region 20T of the GaN transistor 20 is aligned with the long-side direction of the active region 60T of the clamp transistor 60.

(1-5) As viewed in the long-side direction of the active region 20T of the GaN transistor 20 (y-direction), the clamp capacitor 31 and the pull-down resistor 32 are arranged to overlap the drain pad 51 in the short-side direction of the active region 20T of the GaN transistor 20 (x-direction).

In this structure, the clamp capacitor 31 and the pull-down resistor 32 are formed in a region of the semiconductor substrate 11 other than the active regions 20T and 60T. Thus, as viewed in the z-direction, an increase in the area of the semiconductor substrate 11 is limited.

(1-6) The semiconductor device 10 includes the first interconnect layer L1, the second interconnect layer L2 and the third interconnect layer L3 arranged closer to the semiconductor substrate 11 than the first interconnect layer L1 is, and the fourth interconnect layer L4 arranged at a side of the second interconnect layer L2 and the third interconnect layer L3 opposite from the first interconnect layer L1. The drain pad 51, the main source pad 52, the sense source pad 53, and the gate pad 54 are formed in the first interconnect layer L1. The first interconnect 71, the second interconnect 72, the third interconnect 73, the fourth interconnect 74, and the fifth interconnect 75 are formed in the second interconnect layer L2 and the third interconnect layer L3. The GaN transistor 20 is formed in the fourth interconnect layer L4. The clamp transistor 60, the clamp capacitor 31, and the pull-down resistor 32 are arranged in the fourth interconnect layer L4.

With this structure, the GaN transistor 20, the clamp transistor 60, the clamp capacitor 31, and the pull-down resistor 32 are formed in the common interconnect layer. This allows the GaN transistor 20, the clamp transistor 60, the clamp capacitor 31, and the pull-down resistor 32 to be partially formed from the same material. Thus, the semiconductor device 10 is readily manufactured.

(1-7) The semiconductor module 100 includes the semiconductor device 10, the encapsulation resin 110 encapsulating the semiconductor device 10, the drain terminal 121 exposed from the encapsulation resin 110 and electrically connected to the drain pad 51, the main source terminal 122 exposed from the encapsulation resin 110 and electrically connected to the main source pad 52, and the gate terminal 124 exposed from the encapsulation resin 110 and electrically connected to the gate pad 54. The semiconductor module 100 includes the interconnects 130 electrically connecting the semiconductor device 10 to the drain terminal 121, the main source terminal 122, and the gate terminal 124. The drain terminal 121, the main source terminal 122, and the gate terminal 124 are exposed from the resin front surface 110s of the encapsulation resin 110, which faces in the same direction as the substrate front surface 11s of the semiconductor substrate 11.

With this structure, in plan view, the drain terminal 121, the main source terminal 122, and the gate terminal 124 are arranged to overlap the semiconductor substrate 11. This allows for reduction in the size of the semiconductor module 100. In addition, the conductive path from the semiconductor device 10 to the drain terminal 121, the main source terminal 122, and the gate terminal 124 is shortened as compared to a structure in which the drain terminal 121, the main source terminal 122, and the gate terminal 124 are electrically connected to the semiconductor device 10 by, for example, wires. As a result, parasitic inductance caused by the length of the conductive path is reduced. The parasitic inductance of the conductive path affects a switching property (switching speed) of the GaN transistor 20. Therefore, the switching property of the GaN transistor 20 is improved by the reduction of the parasitic inductance.

### Second Embodiment

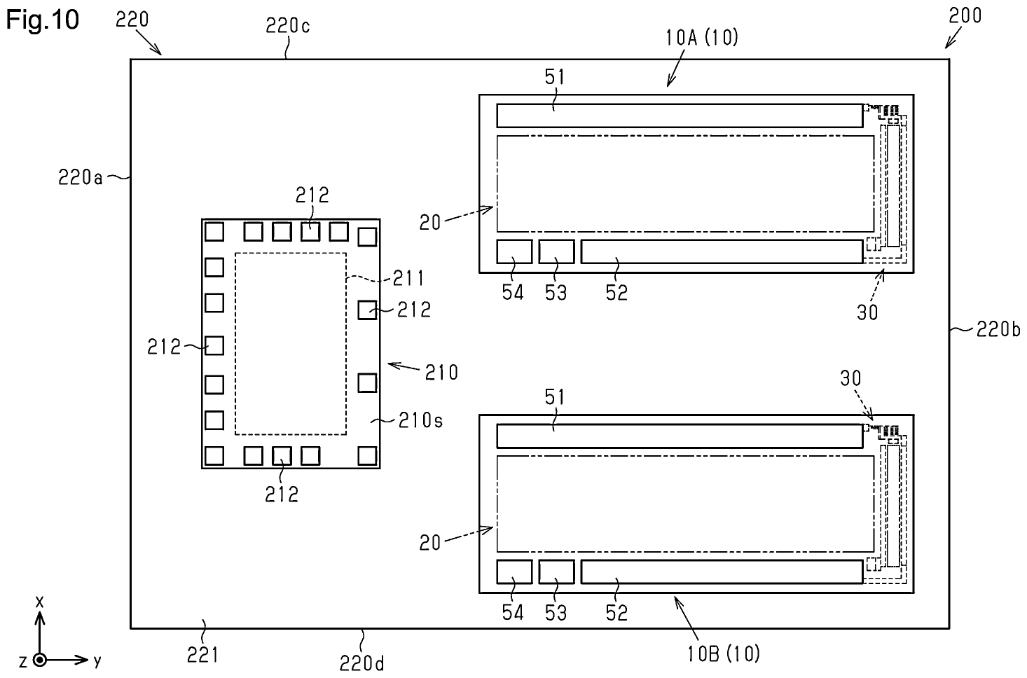

With reference to FIGS. 10 to 15, the configuration of a semiconductor device 10 and a semiconductor module 200 in a second embodiment will now be described. In the description below, the same reference characters are given to those components that are the same as the corresponding components of the first embodiment. Such components will not be described in detail.

### Configuration of Semiconductor Module

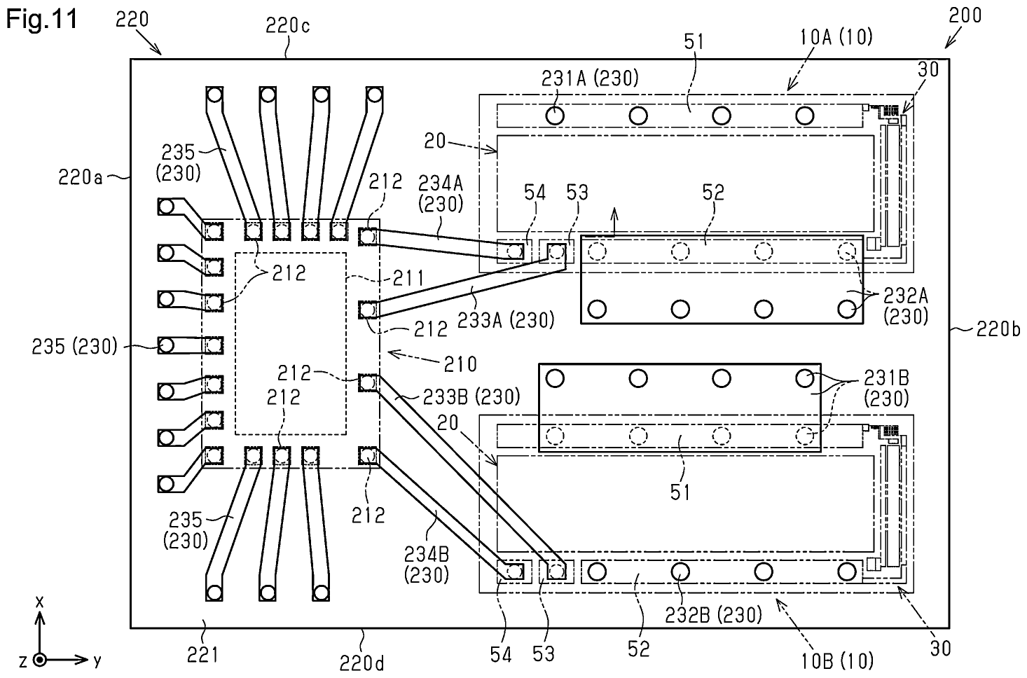

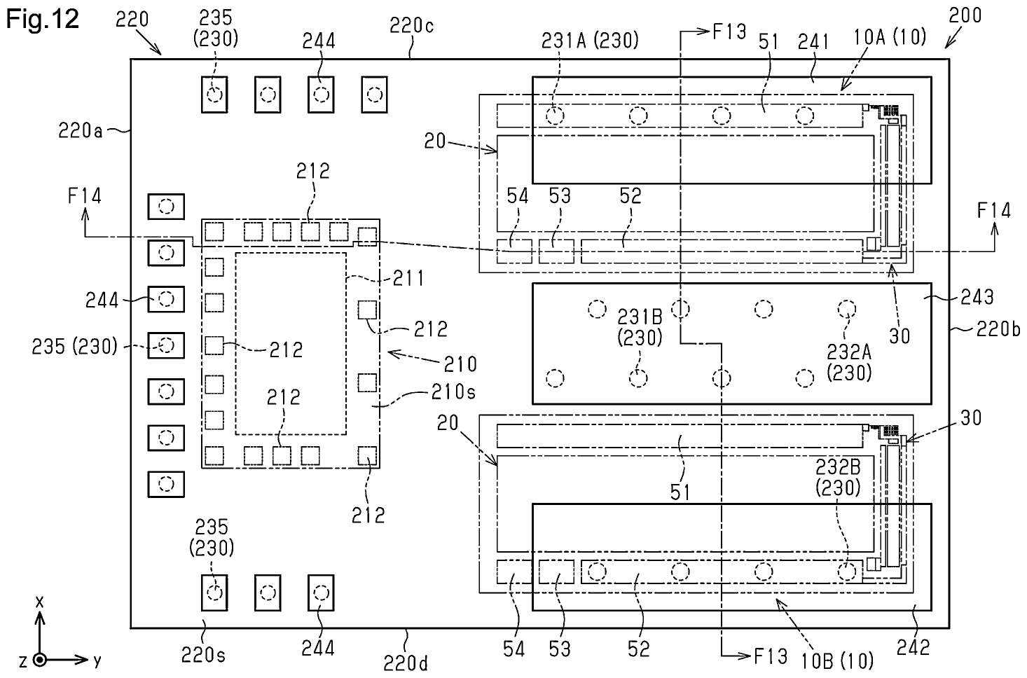

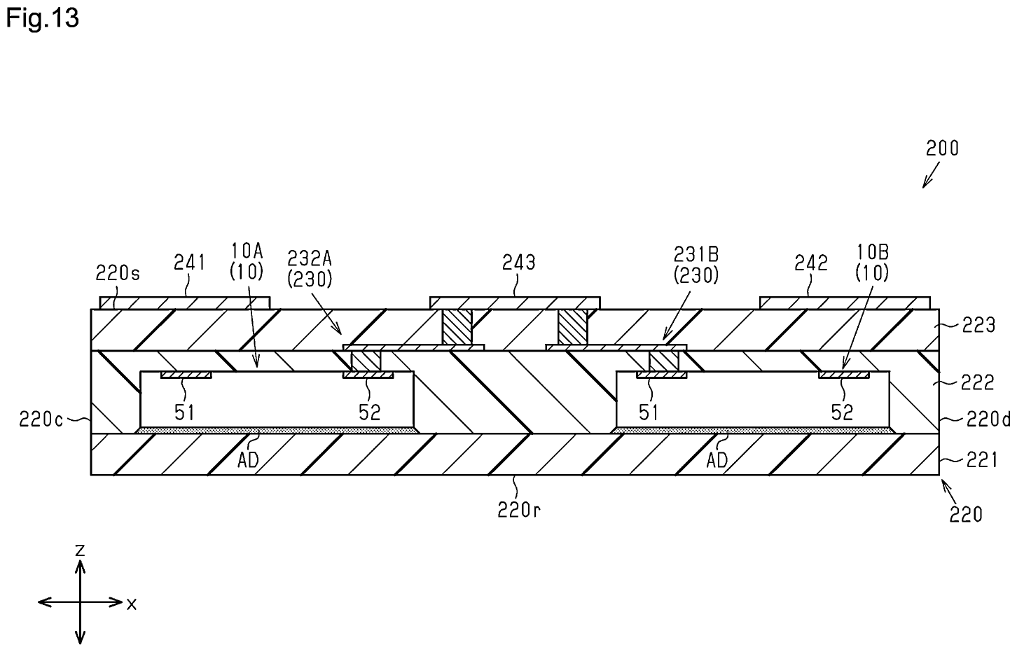

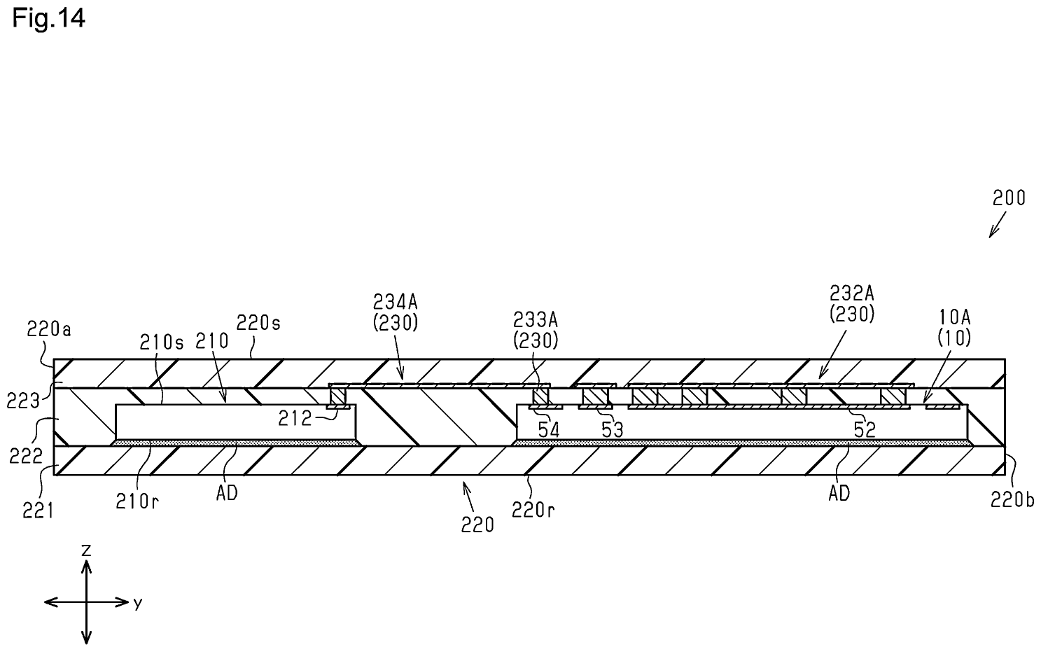

The configuration of the semiconductor module 200 will be described with reference to FIGS. 10 to 14. FIG. 10 is a plan view of the internal structure of the semiconductor module 200 mainly showing an example of an arrangement of a semiconductor chip. FIG. 11 is a plan view of the internal structure of the semiconductor module 200 mainly showing an example of a structure of an interconnect layer. FIG. 12 is a plan view of the semiconductor module 200. FIG. 13 is a cross-sectional view of the semiconductor module 200 taken along line F13-F13 in FIG. 12. FIG. 14 is a cross-sectional view of the semiconductor module 200 taken along line F14-F14 in FIG. 12.

As shown in FIG. 10, the semiconductor module 200 includes multiple (in the present embodiment, two) semiconductor devices 10, a driver chip 210 configured to separately drive the semiconductor devices 10, and an encapsulation resin 220 encapsulating the semiconductor devices 10 and the driver chip 210. In FIG. 10, to facilitate illustration, the semiconductor devices 10 and the driver chip 210 arranged in the encapsulation resin 220 are indicated by solid lines.

The semiconductor module 200 has the form of a rectangular plate. The encapsulation resin 220 defines outer surfaces of the semiconductor module 200. That is, the encapsulation resin 220 has the form of a rectangular plate. The encapsulation resin 220 includes a resin front surface 220s and a resin back surface 220r (refer to FIG. 13) that face opposite directions and first to fourth resin side surfaces 220a to 220d, which are four resin side surfaces intersecting the resin front surface 220s and the resin back surface 220r. In the present embodiment, the first to fourth resin side surfaces 220a to 220d are orthogonal to the resin front surface 220s and the resin back surface 220r. In the present embodiment, the thickness-wise direction of the encapsulation resin 220 refers to the z-direction.

In plan view, the encapsulation resin 220 is rectangular and has a long-side direction and a short-side direction. In the present embodiment, the long-side direction of the encapsulation resin 220 refers to the y-direction. The short-side direction of the encapsulation resin 220 refers to the x-direction. In the present embodiment, the first resin side surface 220a and the second resin side surface 220b define opposite end surfaces in the y-direction. The third resin side surface 220c and the fourth resin side surface 220d define opposite end surfaces in the x-direction. The encapsulation resin 220 is formed from an insulative resin material. Such a resin material includes, for example, an epoxy resin, an acrylic resin, and a phenol resin.

The two semiconductor devices 10 are aligned with each other in the y-direction and separated from each other in the x-direction. Thus, the x-direction refers to a direction in which the two semiconductor devices 10 are arranged. In the present embodiment, the x-direction corresponds to a “first direction.” In plan view, each semiconductor device 10 is off-center of the encapsulation resin 220 in the y-direction. In the present embodiment, in plan view, each semiconductor device 10 is located closer to the second resin side surface 220b of the encapsulation resin 220 than to the first resin side surface 220a. The semiconductor device 10 is arranged so that the long-side direction of the semiconductor substrate 11 is aligned with the y-direction and the short-side direction of the semiconductor substrate 11 is aligned with the x-direction. In other words, the long-side direction of the semiconductor substrate 11 is aligned with the long-side direction of the encapsulation resin 220. The short-side direction of the semiconductor substrate 11 is aligned with the short-side direction of the encapsulation resin 220. The two semiconductor devices 10 are separated from each other in the short-side direction of the encapsulation resin 220. In the description hereafter, for the sake of brevity, the semiconductor device 10 located toward the third resin side surface 220c is referred to as a “semiconductor device 10A.” The semiconductor device 10 located toward the fourth resin side surface 220d is referred to as a “semiconductor device 10B.” When the semiconductor devices 10A and 10B are not distinguished from each other, they are simply referred to as “semiconductor devices 10.”

In plan view, the driver chip 210 is separated from the semiconductor devices 10 in a direction orthogonal to the arrangement direction of the semiconductor devices 10. More specifically, the driver chip 210 is located closer to the first resin side surface 220a than the semiconductor devices 10 are in the y-direction. In the present embodiment, the y-direction corresponds to a “second direction.” The driver chip 210 has the form of a rectangular plate. In plan view, the driver chip 210 is rectangular and has a long-side direction and a short-side direction. In the present embodiment, the driver chip 210 is arranged so that the long-side direction of the driver chip 210 is aligned with the x-direction and the short-side direction of the driver chip 210 is aligned with the y-direction. Thus, in plan view, the long-side direction of the driver chip 210 is orthogonal to the long-side direction of the encapsulation resin 220 and the long-side direction of the semiconductor substrate 11. The short-side direction of the driver chip 210 is orthogonal to the short-side direction of the encapsulation resin 220 and the short-side direction of the semiconductor substrate 11. As viewed in the y-direction, the driver chip 210 is arranged to overlap each of the semiconductor devices 10. In the present embodiment, the driver chip 210 is arranged in the center of the encapsulation resin 220 in the x-direction. The arrangement of the driver chip 210 and the semiconductor devices 10 may be changed in any manner.

The driver chip 210 includes a chip front surface 210s and a chip back surface 210r that face opposite directions in the z-direction (refer to FIG. 14). The chip front surface 210s faces the same direction as the resin front surface 220s. The chip back surface 210r faces the same direction as the resin back surface 220r.

The driver chip 210 includes a semiconductor substrate, a driver circuit 211 formed on the semiconductor substrate and configured to drive each semiconductor device 10, and electrode pads 212 electrically connected to the driver circuit 211. The electrode pads 212 are exposed from the chip front surface 210s.

FIG. 11 shows the internal configuration of a part located above the semiconductor device 10 and the driver chip 210 in the encapsulation resin 220. In FIG. 11, the semiconductor devices 10 and the driver chip 210 are indicated by double-dashed lines for the sake of convenience.

As shown in FIG. 11, the semiconductor module 200 includes an interconnect layer 230. The interconnect layer 230 includes at least two types of interconnect layer. One type of interconnect layer includes a via extending in the z-direction and an interconnect extending in a direction orthogonal to the z-direction. The other type of interconnect layer includes only a via extending in the z-direction.

The interconnect layer 230 includes drain interconnects 231A and 231B, main source interconnects 232A and 232B, sense source interconnects 233A and 233B, gate interconnects 234A and 234B, and driver interconnects 235.

The drain interconnect 231A is electrically connected to the drain pad 51 of the semiconductor device 10A. The drain interconnect 231A includes, for example, multiple vias.

The drain interconnect 231B is electrically connected to the drain pad 51 of the semiconductor device 10B. The drain interconnect 231B includes, for example, first vias connected to the drain pad 51, an interconnect extending in the y-direction so as to connect upper surfaces of the first vias, and second vias formed on the interconnect. The second vias and the first vias are located at different positions in plan view. More specifically, in plan view, the second vias are located closer to the semiconductor device 10A than the first vias are. In other words, in plan view, the second vias are located between the semiconductor device 10A and the semiconductor device 10B in the x-direction.

The main source interconnect 232A is electrically connected to the main source pad 52 of the semiconductor device 10A. The main source interconnect 232A includes, for example, first vias connected to the main source pad 52, an interconnect extending in the y-direction so as to connect upper surfaces of the first vias, and second vias formed on the interconnect. The second vias and the first vias are located at different positions in plan view. More specifically, in plan view, the second vias are located closer to the semiconductor device 10B than the first vias are. In other words, in plan view, the second vias are located between the semiconductor device 10A and the semiconductor device 10B in the x-direction. The second vias are located closer to the semiconductor device 10A than the second vias of the drain interconnect 231B are.

The main source interconnect 232B is electrically connected the main source pad 52 of the semiconductor device 10B. The main source interconnect 232B includes, for example, multiple vias.

The sense source interconnect 233A electrically connects the sense source pad 53 of the semiconductor device 10A and the driver circuit 211. The sense source interconnect 233A includes, for example, a first via connected to the sense source pad 53 of the semiconductor device 10A, a second via connected to the electrode pad 212 of the driver chip 210, and an interconnect connecting the first via and the second via.

The sense source interconnect 233B electrically connects the sense source pad 53 of the semiconductor device 10B and the driver circuit 211. The sense source interconnect 233B includes, for example, a first via connected to the sense source pad 53 of the semiconductor device 10B, a second via connected to the electrode pad 212 of the driver chip 210, and an interconnect connecting the first via and the second via.

The gate interconnect 234A electrically connects the gate pad 54 of the semiconductor device 10A and the driver circuit 211. The gate interconnect 234A includes, for example, a first via connected to the gate pad 54 of the semiconductor device 10A, a second via connected to the electrode pad 212 of the driver chip 210, and an interconnect connecting the first via and the second via.

The gate interconnect 234B electrically connects the gate pad 54 of the semiconductor device 10B and the driver circuit 211. The gate interconnect 234B includes, for example, a first via connected to the gate pad 54 of the semiconductor device 10B, a second via connected to the electrode pad 212 of the driver chip 210, and an interconnect connecting the first via and the second via.

The driver interconnects 235 are separately connected to the electrode pads 212 of the driver chip 210. Each of the driver interconnects 235 includes a first via connected to the electrode pad 212 of the driver chip 210, an interconnect extending from the upper surface of the first via in a direction orthogonal to the z-direction, and second vias formed on the interconnect. In plan view, the interconnect extends outward beyond the driver chip 210 toward any one of the first resin side surface 220a, the third resin side surface 220c, and the fourth resin side surface 220d.

As shown in FIG. 12, the semiconductor module 200 includes a drain terminal 241, a source terminal 242, an output terminal 243, and driver terminals 244. The terminals 241 to 244 are exposed from the resin front surface 220s.

The drain terminal 241, the source terminal 242, and the output terminal 243 are aligned with each other in the y-direction and separated from each other in the x-direction. In plan view, the drain terminal 241, the source terminal 242, and the output terminal 243 are each rectangular so that the long sides extend in the y-direction and the short sides extend in the x-direction. The drain terminal 241, the source terminal 242, and the output terminal 243 are located closer to the second resin side surface 220b than to the first resin side surface 220a in the y-direction. In plan view, the drain terminal 241 is arranged to overlap the semiconductor device 10A, the source terminal 242 is arranged to overlap the semiconductor device 10B, and the output terminal 243 is arranged between the semiconductor device 10A and the semiconductor device 10B in the x-direction. The arrangement of the drain terminal 241, the source terminal 242, and the output terminal 243 may be changed in any manner.

The driver terminals 244 are located closer to the first resin side surface 220a than to the second resin side surface 220b in the y-direction. In plan view, the driver terminals 244 are arranged in line along each of the first resin side surface 220a, the third resin side surface 220c, and the fourth resin side surface 220d.

The drain terminal 241 is electrically connected to the drain electrode 29 of the semiconductor device 10A by the vias of the drain interconnect 231A. The source terminal 242 is electrically connected to the source electrode 28 of the semiconductor device 10B by the vias of the main source interconnect 232B. The output terminal 243 is electrically connected to the source electrode 28 of the semiconductor device 10A and the drain electrode 29 of the semiconductor device 10B by the second vias of the main source interconnect 232A and the second vias of the drain interconnect 231B. The driver terminals 244 are electrically connected to the driver circuit 211 by the second vias of the respective driver interconnects 235.

As shown in FIGS. 13 and 14, the encapsulation resin 220 includes a first encapsulation portion 221, a second encapsulation portion 222, and a third encapsulation portion 223. The encapsulation portions 221 to 223 are formed from, for example, the same material.

The first encapsulation portion 221 is a support member supporting the semiconductor devices 10 and the driver chip 210. The semiconductor devices 10 and the driver chip 210 are bonded to the first encapsulation portion 221 by, for example, the bonding material AD. The first encapsulation portion 221 includes the resin back surface 220r.

The second encapsulation portion 222 cooperates with the first encapsulation portion 221 to encapsulate the semiconductor devices 10 and the driver chip 210.

The third encapsulation portion 223 is arranged on the second encapsulation portion 222. The third encapsulation portion 223 includes the resin front surface 220s. The drain terminal 241, the source terminal 242, the output terminal 243, and the driver terminals 244 are formed on the third encapsulation portion 223.

The interconnect layer 230 is formed in the second encapsulation portion 222 and the third encapsulation portion 223.

As shown in FIG. 13, the drain interconnect 231B and the main source interconnect 232A of the interconnect layer 230 are formed as follows. The first vias of the drain interconnect 231B and the main source interconnect 232A extend in the z-direction through part of the second encapsulation portion 222 that covers the semiconductor devices 10A and 10B. The interconnects of the drain interconnect 231B and the main source interconnect 232A are formed on the second encapsulation portion 222. The interconnects are covered by the third encapsulation portion 223. The second vias of the drain interconnect 231B and the main source interconnect 232A extend through the third encapsulation portion 223 in the z-direction. Although not shown in FIG. 13, in the interconnect layer 230, the drain interconnect 231A and the main source interconnect 232B (refer to FIG. 11) include vias extending in the z-direction through part of the second encapsulation portion 222 that covers the semiconductor devices 10A and 10B and vias extending in the z-direction through the third encapsulation portion 223.

As shown in FIG. 14, in the interconnect layer 230, the sense source interconnects 233A and 233B and the gate interconnects 234A and 234B (refer to FIG. 11) are formed as described below. The first via of the gate interconnect 234A extends in the z-direction through part of the second encapsulation portion 222 that covers the semiconductor device 10A. The interconnect of the gate interconnect 234A is formed on the second encapsulation portion 222. The interconnect is covered by the third encapsulation portion 223. The second via of the gate interconnect 234A extends in the z-direction through part of the second encapsulation portion 222 that covers the driver chip 210. The connecting structures of the sense source interconnects 233A and 233B and the gate interconnect 234B are the same as those of the gate interconnect 234A and thus will not be described in detail.

### Circuit Configuration of Semiconductor Module

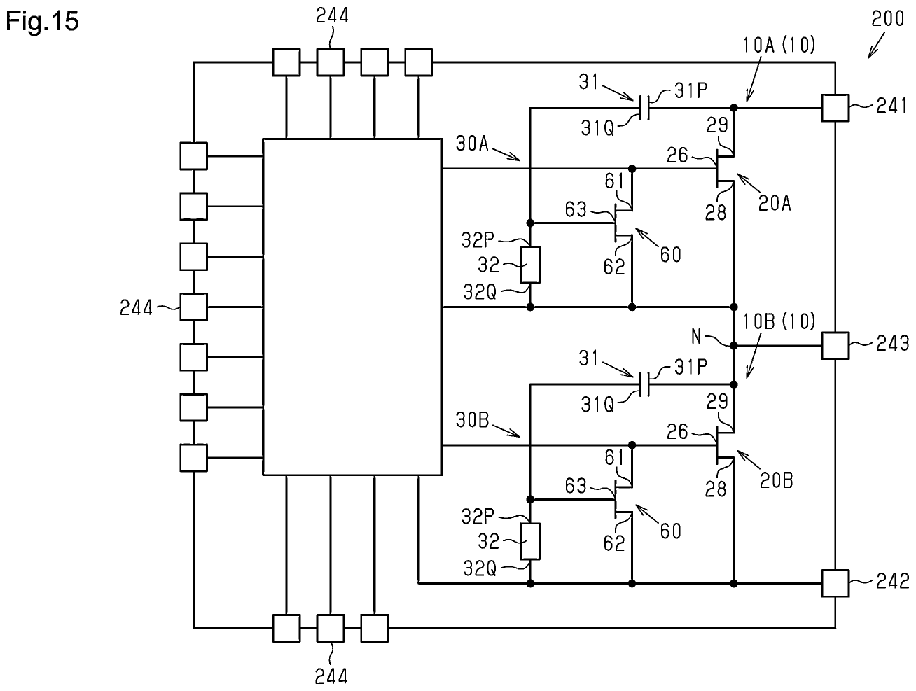

FIG. 15 shows an example of the circuit configuration of the semiconductor module 200. To facilitate illustration, the details of the circuit configuration of the driver circuit 211 are not shown. In the description hereafter, the GaN transistor of the semiconductor device 10A is referred to as a “GaN transistor 20A.” The GaN transistor of the semiconductor device 10B is referred to as a “GaN transistor 20B.” The active clamp circuit 30 of the semiconductor device 10A is referred to as an “active clamp circuit 30A.” The active clamp circuit 30 of the semiconductor device 10B is referred to as an “active clamp circuit 30B.”

As shown in FIG. 15, in the same manner as the first embodiment, the GaN transistor 20A is connected to the active clamp circuit 30A, and the GaN transistor 20B is connected to the active clamp circuit 30B.

The drain electrode 29 of the GaN transistor 20A is connected to the drain terminal 241. The source electrode 28 of the GaN transistor 20B is connected to the source terminal 242.

The source electrode 28 of the GaN transistor 20A is connected to the drain electrode 29 of the GaN transistor 20B. The output terminal 243 is connected to a node N located between the source electrode 28 of the GaN transistor 20A and the drain electrode 29 of the GaN transistor 20B.

The gate electrodes 26 of the GaN transistors 20A and 20B are connected to the driver circuit 211. The source electrodes 28 of the GaN transistors 20A and 20B are connected to the driver circuit 211. The driver circuit 211 is connected to the driver terminals 244.

In the semiconductor module 200, when the driver terminals 244 receive a control signal for driving the GaN transistors 20A and 20B from an external device, the driver circuit 211 generates a drive signal for driving the GaN transistors 20A and 20B in accordance with the control signal, which is input to the driver circuit 211 through the driver terminals 244. The driver circuit 211 transmits the drive signal to the gate electrodes 26 of the GaN transistors 20A and 20B. The GaN transistors 20A and 20B are turned on and off based on the drive signal input to the gate electrodes 26 in a complementary manner.

### Advantages

The second embodiment has the following advantages in addition to the advantages of the first embodiment.

(2-1) The semiconductor module 200 includes the semiconductor devices 10A and 10B, the driver chip 210, and the encapsulation resin 220 encapsulating the semiconductor devices 10A and 10B and the driver chip 210.

In this structure, the GaN transistors 20 of the semiconductor devices 10A and 10B and the driver circuit 211 of the driver chip 210 are electrically connected to each other in the semiconductor module 200. Thus, the conductive paths from the GaN transistors 20 of the semiconductor devices 10A and 10B to the driver circuit 211 are shortened as compared to a structure in which the GaN transistors 20 of the semiconductor devices 10A and 10B and the driver circuit 211 are electrically connected on a circuit substrate arranged outside the semiconductor module 200. As a result, parasitic inductance and parasitic inductance caused by the length of the conductive paths are reduced.

(2-2) In plan view, the driver chip 210 is separated from the semiconductor devices 10A and 10B in a direction orthogonal to the arrangement direction of the semiconductor devices 10A and 10B.

This structure limits variations between the semiconductor device 10A and the semiconductor device 10B in the length of the conductive path extending from the gate electrode 26 of the GaN transistor 20 to the driver circuit 211 as compared to a structure in which the driver chip 210 is arranged next to one of the semiconductor devices 10A and 10B in the arrangement direction of the semiconductor devices 10A and 10B.

### Modified Examples

The embodiments described above may be modified as follows. The embodiments described above and the modified examples described below can be combined as long as the combined modifications remain technically consistent with each other.

### Configuration of Semiconductor Device in Modified Examples

In each embodiment, the sense source pad 53 may be omitted from the semiconductor device 10. In this case, in the first embodiment, the sense source terminal 123 may be omitted from the semiconductor module 100.

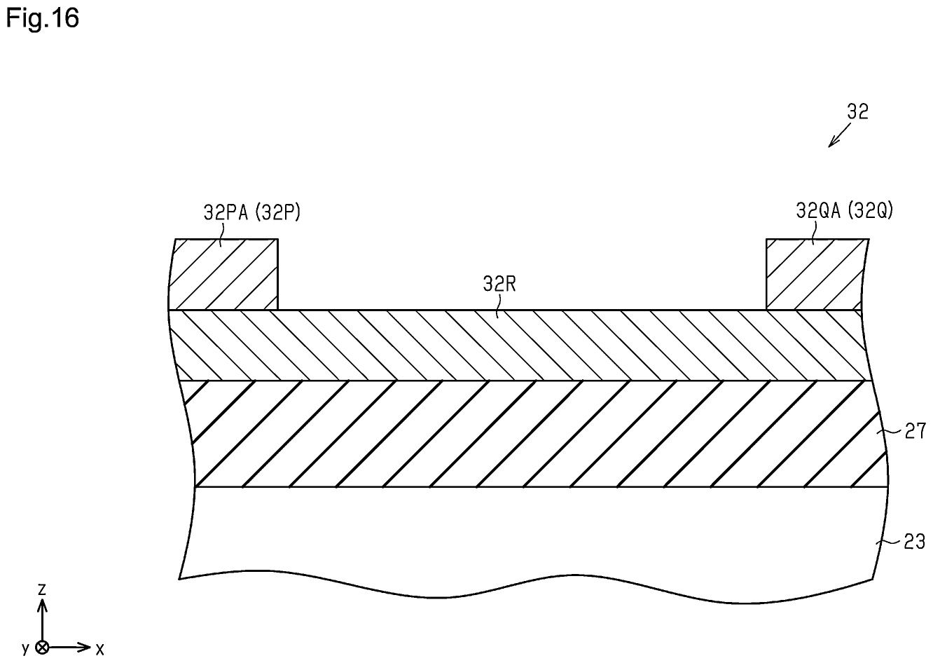

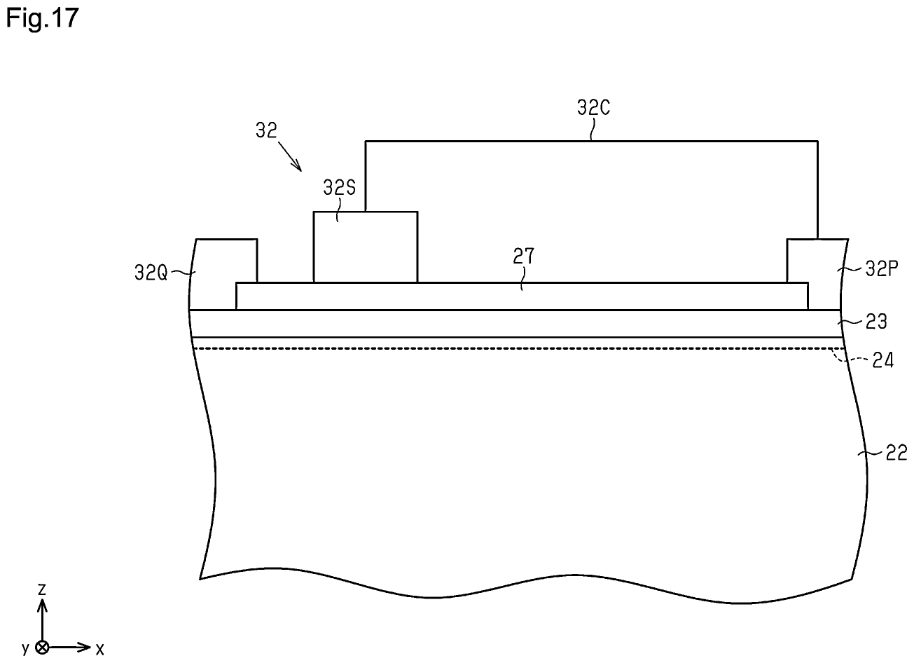

In each embodiment, the configuration of the pull-down resistor 32 may be changed in any manner. The pull-down resistor 32 may be changed as in a first modified example shown in FIG. 16 or a second modified example shown in FIG. 17.

As shown in FIG. 16, in the first modified example, the pull-down resistor 32 includes a first interconnect part 32PA including the first terminal 32P, a second interconnect part 32QA including the second terminal 32Q, and a flat resistor part 32R. The interconnect parts 32PA and 32QA may be formed from, for example, any conductive material including at least one of Cu, Al, an AlCu alloy, W, Ti, and TiN.

The resistor part 32R is formed on the semiconductor substrate 11 (refer to FIG. 4). More specifically, the resistor part 32R is formed on the passivation layer 27 formed on the semiconductor substrate 11. The position where the resistor part 32R is formed is not limited to on the passivation layer 27 and may be anywhere on the insulation layer covering the electron supply layer 23.

The resistor part 32R is formed from a material having a greater resistance than the material forming the first interconnect part 32PA and the second interconnect part 32QA. In an example, the resistor part 32R is formed from, for example, polysilicon.

The first interconnect part 32PA and the second interconnect part 32QA are arranged on the resistor part 32R. The first interconnect part 32PA and the second interconnect part 32QA are electrically connected to the resistor part 32R. More specifically, the interconnect parts 32PA and 32QA are in ohmic contact with the resistor part 32R. In plan view, the first interconnect part 32PA and the second interconnect part 32QA are separately formed on two ends of the resistor part 32R in the x-direction.

As shown in FIG. 17, in the second modified example, the pull-down resistor 32 includes a normally-on transistor and is configured to include an on-resistance of the normally-on transistor. More specifically, in the same manner as the GaN transistor 20 and the clamp transistor 60 of the embodiments, the pull-down resistor 32 includes the electron transit layer 22, the electron supply layer 23, and the passivation layer 27. However, the pull-down resistor 32 does not include the gate layer 25, which differs from the GaN transistor 20 and the clamp transistor 60 of the embodiments. The pull-down resistor 32 includes the first terminal 32P corresponding to a drain electrode, the second terminal 32Q corresponding to a source electrode, a third terminal 32S corresponding to a gate electrode, and the connection path 32A (refer to FIG. 4) electrically connecting the first terminal 32P and the second terminal 32Q. The connection path 32A has a serpentine shape in the same manner as the first embodiment. The third terminal 32S is formed on the passivation layer 27. The third terminal 32S is arranged toward the second terminal 32Q.

The pull-down resistor 32 includes a wire 32C connecting the first terminal 32P and the third terminal 32S. The wire 32C may be formed from, for example, any conductive material including at least one of Cu, Al, an AlCu alloy, W, Ti, and TiN. The wire 32C is formed, for example, in the second interconnect layer L2 and the third interconnect layer L3 (refer to FIG. 5).

In each embodiment, in plan view, the positions where the GaN transistor 20 and the clamp transistor 60 are formed may be changed in any manner. In an example, the GaN transistor 20 and the clamp transistor 60 may be arranged next to each other in the short-side direction of the semiconductor substrate 11 (x-direction). In this case, the active region 60T of the clamp transistor 60 is formed so that, for example, the long sides extend in the y-direction and the short sides extend in the x-direction. Also, for example, in plan view, the clamp capacitor 31 and the pull-down resistor 32 are formed in a position differing form the positions of the GaN transistor 20 and the clamp transistor 60 in the long-side direction of the semiconductor substrate 11 (y-direction).

In each embodiment, in plan view, the positions where the clamp capacitor 31 and the pull-down resistor 32 are formed may be changed in any manner. In an example, as viewed in the long-side direction of the active region 20T of the GaN transistor 20 (y-direction), the clamp capacitor 31 and the pull-down resistor 32 may be formed so as not to overlap the drain pad 51 in the short-side direction of the active region 20T (x-direction). For example, in plan view, the clamp capacitor 31 and the pull-down resistor 32 may be formed at a position closer to the third side surface 11c of the semiconductor substrate 11 than the drain pad 51 is.

In each embodiment, in the thickness-wise direction of the semiconductor substrate 11 (z-direction), the positions where the clamp capacitor 31 and the pull-down resistor 32 are formed may be changed in any manner. In an example, the clamp capacitor 31 and the pull-down resistor 32 may be formed in the second interconnect layer L2.

### Circuit Configuration of Active Clamp Circuit in Modified Examples

In each embodiment, the circuit configuration of the active clamp circuit 30 may be changed in any manner. In an example, the active clamp circuit 30 may be changed as in first to third modified examples described below.

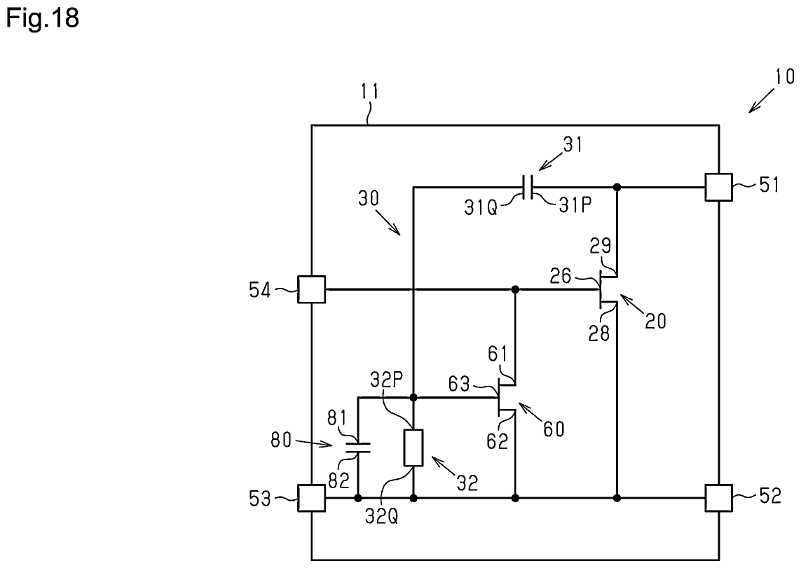

FIG. 18 shows the circuit configuration of the active clamp circuit 30 in the first modified example.

As shown in FIG. 18, in the first modified example, the active clamp circuit 30 further includes a capacitor 80 connected between the source electrode 62 and the gate electrode 63 of the clamp transistor 60. The capacitor 80 is configured to inhibit application of a voltage higher than the gate-source rated voltage to the gate electrode 63 of the clamp transistor 60. Thus, the gate-source voltage of the clamp transistor 60 is less likely to increase excessively.

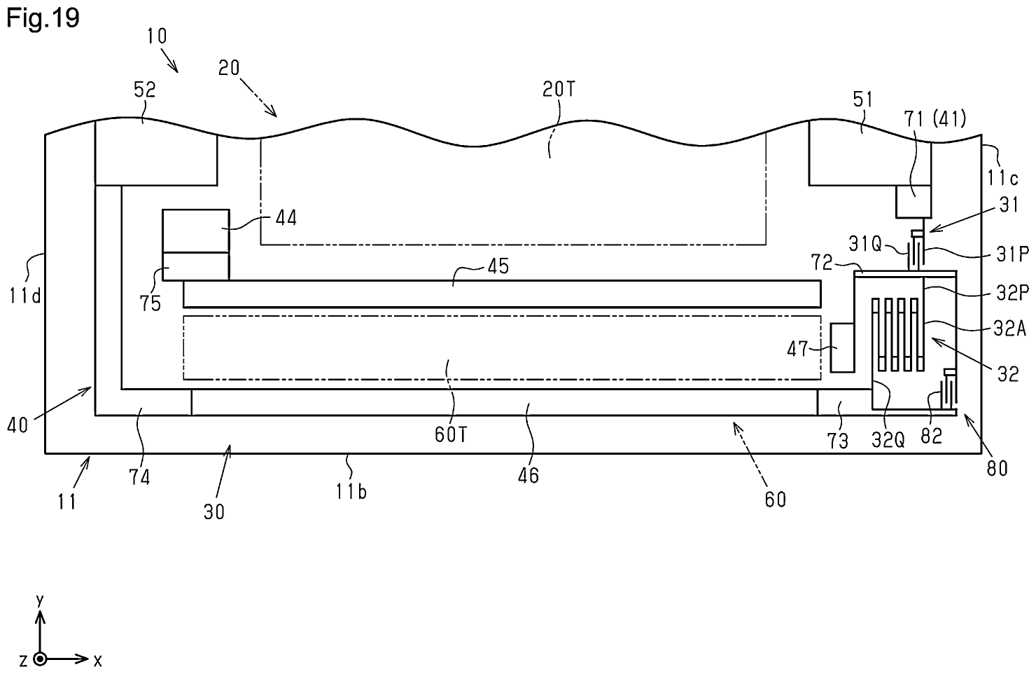

FIG. 19 shows the configuration of the active clamp circuit 30 arranged on the semiconductor substrate 11 in the first modified example.

As shown in FIG. 19, in plan view, the capacitor 80 is formed on an end of the semiconductor substrate 11 located at the second side surface 11b and the third side surface 11c. The capacitor 80 is formed at a position closer to the third side surface 11c than the active region 60T of the clamp transistor 60 is. In the illustrated example, in plan view, the capacitor 80 is formed at a position closer to the third side surface 11c than the clamp capacitor 31 is. The capacitor 80 is formed at a position closer to the second side surface 11b than the clamp capacitor 31 is.

The capacitor 80 includes a first electrode 81 and a second electrode 82. The first electrode 81 is electrically connected to the second electrode 31Q of the clamp capacitor 31. The second electrode 82 is electrically connected to the source electrode 62 of the clamp transistor 60. The capacitor 80 is configured in the same manner as the clamp capacitor 31. Hence, although not shown, the capacitor 80 is formed in the third interconnect layer L3.

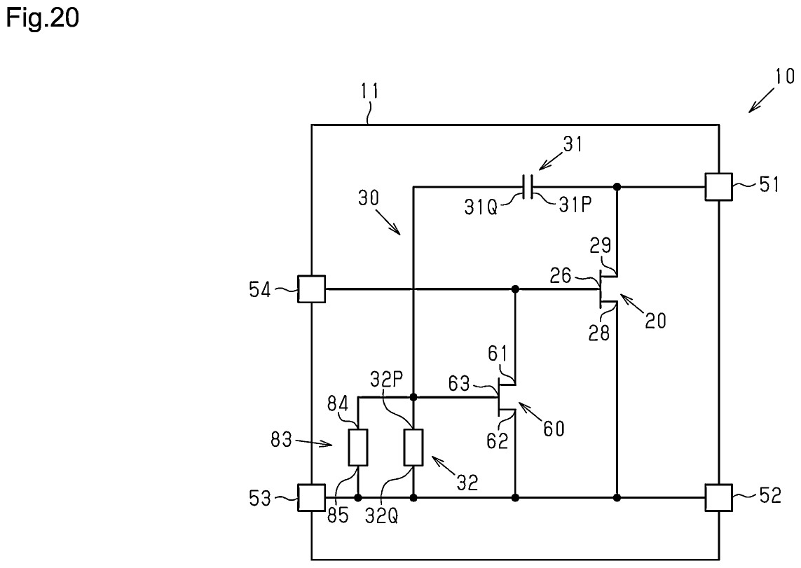

FIG. 20 shows the circuit configuration of the active clamp circuit 30 in the second modified example.

As shown in FIG. 20, in the second modified example, the active clamp circuit 30 further includes a shunt resistor 83 connected between the source electrode 62 and the gate electrode 63 of the clamp transistor 60. The shunt resistor 83 is configured to inhibit application of a voltage higher than the gate-source rated voltage to the gate electrode 63 of the clamp transistor 60. Thus, the gate-source voltage of the clamp transistor 60 is less likely to increase excessively.

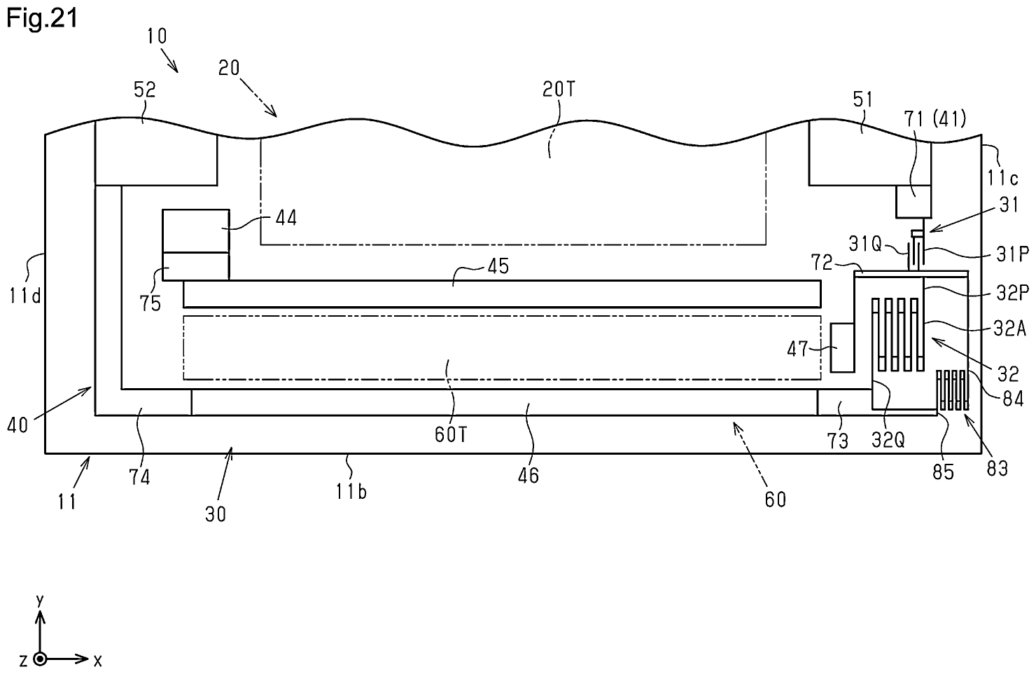

FIG. 21 shows the configuration of the active clamp circuit 30 arranged on the semiconductor substrate 11 in the second modified example.

As shown in FIG. 21, in plan view, the shunt resistor 83 is formed on an end of the semiconductor substrate 11 at the second side surface 11b and the third side surface 11c. The shunt resistor 83 is formed at a position closer to the third side surface 11c than the active region 60T of the clamp transistor 60 is. In the illustrated example, in plan view, the shunt resistor 83 is formed at a position closer to the third side surface 11c than the clamp capacitor 31 is. The shunt resistor 83 is formed at a position closer to the second side surface 11b than the clamp capacitor 31 is.

The shunt resistor 83 includes a first terminal 84 and a second terminal 85. The first terminal 84 is electrically connected to the second electrode 31Q of the clamp capacitor 31. The second terminal 85 is electrically connected to the source electrode 62 of the clamp transistor 60. The shunt resistor 83 is configured in the same manner as the pull-down resistor 32. Hence, although not shown, the shunt resistor 83 is formed in the third interconnect layer L3.

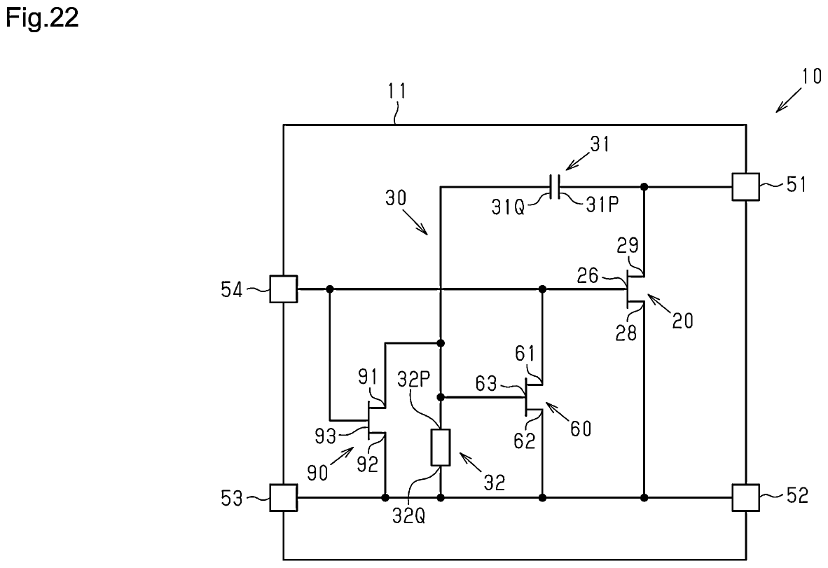

FIG. 22 shows the circuit configuration of the active clamp circuit 30 in the third modified example.

As shown in FIG. 22, in the third modified example, the active clamp circuit 30 further includes a protective transistor 90 that inhibits erroneous activation of the clamp transistor 60. The protective transistor 90 includes a drain electrode 91, a source electrode 92, and a gate electrode 93. The protective transistor 90 is connected between the source electrode 62 and the gate electrode 63 of the clamp transistor 60. More specifically, the drain electrode 91 of the protective transistor 90 is connected to the gate electrode 63 of the clamp transistor 60. The source electrode 92 of the protective transistor 90 is connected to the source electrode 62 of the clamp transistor 60. The gate electrode 93 of the protective transistor 90 is connected to the gate pad 54. The protective transistor 90 is a normally-off transistor in the same manner as the GaN transistor 20.

When the GaN transistor 20 is in an activation state, the protective transistor 90 is in an activation state. The protective transistor 90 connects the gate electrode 63 of the clamp transistor 60 and the source electrode 62 of the clamp transistor 60. Thus, when the GaN transistor 20 is in the activation state, the protective transistor 90 ensures deactivation of the clamp transistor 60. This avoids a situation in which the GaN transistor 20 is turned off at an unintended timing even when noise or the like is applied to an interconnect connected to the gate electrode 63 of the clamp transistor 60.

When the GaN transistor 20 is in a deactivation state, the protective transistor 90 is in a deactivation state. This allows the clamp transistor 60 to be activated in accordance with the drain-source voltage of the GaN transistor 20. Thus, as described in the first embodiment, the clamp transistor 60 limits an increase in the gate-source voltage of the GaN transistor 20.

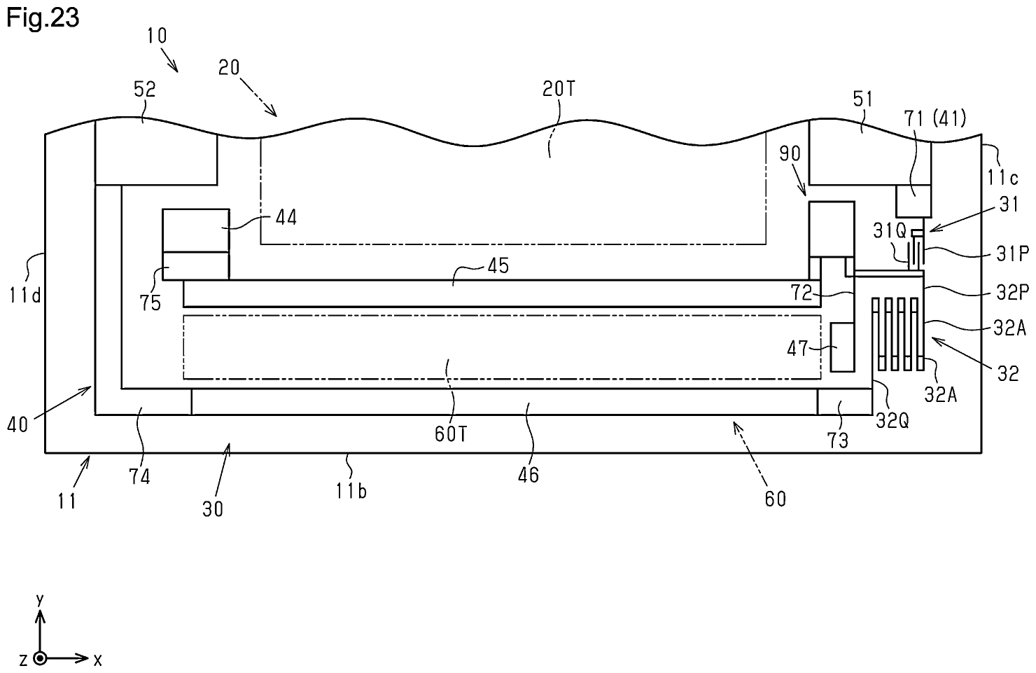

FIG. 23 shows the configuration of the active clamp circuit 30 arranged on the semiconductor substrate 11 in the third modified example.

As shown in FIG. 23, the protective transistor 90 is formed between the active region 20T of the GaN transistor 20 and the active region 60T of the clamp transistor 60 in the y-direction. The drain electrode 91 (refer to FIG. 22) of the protective transistor 90 is electrically connected to the clamp gate interconnect 47. The gate electrode 93 (refer to FIG. 22) of the protective transistor 90 is electrically connected to the clamp drain interconnect 45. Although not shown, the source electrode 92 (refer to FIG. 22) of the protective transistor 90 is electrically connected to the clamp source interconnect 46. Although not shown, the protective transistor 90 is formed in the third interconnect layer L3. In other words, the protective transistor 90 is formed at the same position as the GaN transistor 20 and the clamp transistor 60 in the z-direction.

In at least one of the first modified example and the second modified example, the active clamp circuit 30 may include the protective transistor 90 of the third modified example. In this configuration, while the clamp transistor 60 is protected when the GaN transistor 20 is in a deactivation state, and erroneous activation of the clamp transistor 60 is inhibited when the GaN transistor 20 is in an activation state.

### Modified Examples of Semiconductor Module

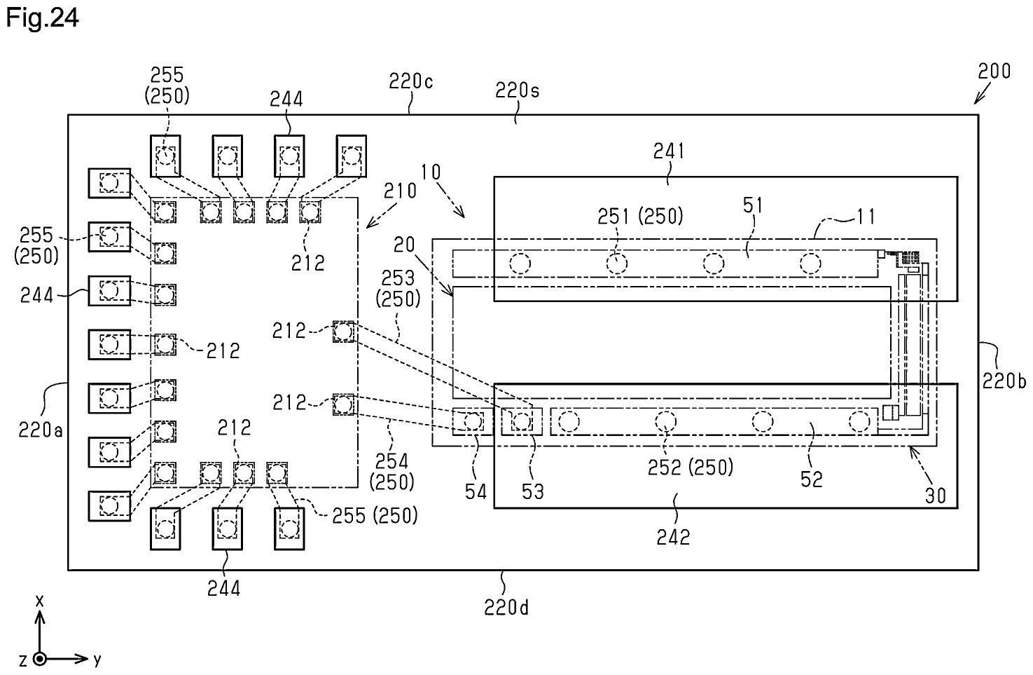

In the second embodiment, the semiconductor module 200 includes two semiconductor devices 10. However, alternatively, for example, as shown in FIG. 24, the semiconductor module 200 may include a single semiconductor device 10.

In plan view, the shape of the encapsulation resin 220 is rectangular so that the long sides extend in the y-direction and the short sides extend in the x-direction.

The semiconductor device 10 and the driver chip 210 are separated from each other in the y-direction. The semiconductor device 10 is located closer to the second resin side surface 220b of the encapsulation resin 220 than the driver chip 210 is in the y-direction. In other words, the driver chip 210 is located closer to the first resin side surface 220a of the encapsulation resin 220 than the semiconductor device 10 is in the y-direction.

The semiconductor device 10 is arranged so that the long-side direction of the semiconductor substrate 11 is aligned with the y-direction and the short-side direction of the semiconductor substrate 11 is aligned with the x-direction. Hence, the long-side direction of the semiconductor substrate 11 is aligned with the long-side direction of the encapsulation resin 220, the short-side direction of the semiconductor substrate 11 is aligned with the short-side direction of the encapsulation resin 220. The driver chip 210 is arranged so that the long-side direction of the driver chip 210 is aligned with the x-direction and the short-side direction of the driver chip 210 is aligned with the y-direction. Hence, in plan view, the long-side direction of the driver chip 210 is orthogonal to the long-side direction of the semiconductor substrate 11 and the long-side direction of the encapsulation resin 220. In plan view, the short-side direction of the driver chip 210 is orthogonal to the short-side direction of the semiconductor substrate 11 and the short-side direction of the encapsulation resin 220.

In the modified example, the semiconductor module 200 includes the drain terminal 241, the source terminal 242, and the driver terminals 244. More specifically, in the modified example, the semiconductor module 200 does not include the output terminal 243. The drain terminal 241 and the source terminal 242 are aligned with each other in the y-direction and separated from each other in the x-direction. In plan view, the drain terminal 241 and the source terminal 242 are arranged to overlap the semiconductor device 10. The driver terminals 244 are located closer to the first resin side surface 220a than the drain terminal 241 and the source terminal 242 are in the y-direction. In other words, the driver terminals 244 are located closer to the first resin side surface 220a than the semiconductor device 10 is in the y-direction.

In the modified example, the semiconductor module 200 includes an interconnect layer 250. The interconnect layer 250 is formed from the same conductive material as that forming the interconnect layer 230 (refer to FIG. 13). The interconnect layer 250 includes a drain interconnect 251, a main source interconnect 252, a sense source interconnect 253, a gate interconnect 254, and driver interconnects 255.

The drain interconnect 251 electrically connects the drain electrode 29 of the GaN transistor 20 and the drain terminal 241. The drain interconnect 251 includes multiple vias.

The main source interconnect 252 electrically connects the source electrode 28 of the GaN transistor 20 and the source terminal 242. The main source interconnect 252 includes multiple vias.

The sense source interconnect 253 electrically connects the source electrode 28 of the GaN transistor 20 and the driver circuit 211 of the driver chip 210. The sense source interconnect 253 is configured in the same manner as the sense source interconnects 233A and 233B (refer to FIG. 13).

The gate interconnect 254 electrically connects the gate electrode 26 of the GaN transistor 20 and the driver circuit 211. The gate interconnect 254 is configured in the same manner as the gate interconnect 234A (refer to FIG. 14).

The driver interconnects 255 separately electrically connect the driver terminals 244 and the driver circuit 211. The driver interconnects 255 have the same structure as the driver interconnects 235 of the second embodiment (refer to FIG. 11).

In the second embodiment, the number of driver chips 210 may be changed in any manner. In an example, the semiconductor module 200 may include multiple driver chips 210. The number of driver chips 210 may be changed in accordance with the number of semiconductor devices 10. In an example, when the number of semiconductor devices 10 is two, the number of driver chips 210 is two.

In each embodiment, in the semiconductor modules 100 and 200, the number of semiconductor devices 10 may be changed in any manner. In an example, the semiconductor module 100 includes two or more semiconductor devices 10. In an example, the semiconductor module 200 includes three or more semiconductor devices 10.

In the first embodiment, in the semiconductor module 100, the drain pad 51, the main source pad 52, the sense source pad 53, and the gate pad 54 of the GaN transistor 20 may be electrically connected to the drain terminal 121, the main source terminal 122, the sense source terminal 123, and the gate terminal 124 by wires. In this case, the terminals 121 to 124 are exposed from, for example, the resin back surface 110r of the encapsulation resin 110.

In the second embodiment, in the semiconductor module 200, the sense source pad 53 and the gate pad 54 of the semiconductor devices 10A and 10B are separately electrically connected to the electrode pads 212 of the driver chip 210 by wires.

In the second embodiment, in the semiconductor module 200, the drain pad 51 and the main source pad 52 of the semiconductor devices 10A and 10B may be separately electrically connected to the drain terminal 241, the source terminal 242, and the output terminal 243 by wires.

In the present disclosure, the term “on” includes the meaning of “above” in addition to the meaning of “on” unless otherwise clearly indicated in the context. Therefore, the phrase “first member formed on second member” is intended to mean that the first member may be formed on the second member in contact with the second member in one embodiment and that the first member may be located above the second member without contacting the second member in another embodiment. In other words, the term “on” does not exclude a structure in which another member is formed between the first member and the second member.

The z-direction as referred to in the present disclosure does not necessarily have to be the vertical direction and does not necessarily have to be fully aligned with the vertical direction. In the structures according to the present disclosure, “upward” and “downward” in the z-direction as referred to in the present description are not limited to “upward” and “downward” in the vertical direction. In an example, the x-direction may be aligned with the vertical direction. In another example, the y-direction may be aligned with the vertical direction.

In this specification, “at least one of A and B” should be understood to mean “only A, only B, or both A and B.”

### CLAUSES

The technical aspects that are understood from the embodiment and the modified examples will be described below. To facilitate understanding without intention to limit, the reference signs of the elements in the embodiments are given to the corresponding elements in the clause with parentheses. The reference signs are used as examples to facilitate understanding, and the components in each clause are not limited to those components given with the reference signs.

### [Clause 1]

A semiconductor device (10), including:
a semiconductor substrate (11);
a GaN transistor (20) formed on the semiconductor substrate (11) and including a drain electrode (29), a source electrode (28), and a gate electrode (26);
an active clamp circuit (30) formed on the semiconductor substrate (11) and electrically connected to the GaN transistor (20), the active clamp circuit (30) including a clamp transistor (60) configured to be activated based on a rise of drain-source voltage of the GaN transistor (20);
a drain pad (51) electrically connected to the drain electrode (29) of the GaN transistor (20);
a source pad (52) electrically connected to the source electrode (28) of the GaN transistor (20); and
a gate pad (54) electrically connected to the gate electrode (26) of the GaN transistor (20).

### [Clause 2]

The semiconductor device according to clause 1, in which
the GaN transistor (20) includes a main drift layer (22),
the clamp transistor (60) includes a sub drift layer (22), and
the sub drift layer (22) and the main drift layer (22) are composed of a same material.

### [Clause 3]

The semiconductor device according to clause 1 or 2, in which
the clamp transistor (60) includes a drain electrode (61), a source electrode (62), and a gate electrode (63),
the source electrode (62) of the clamp transistor (60) is electrically connected to the source electrode (28) of the GaN transistor (20),
the drain electrode (61) of the clamp transistor (60) is electrically connected to the gate electrode (26) of the GaN transistor (20), and
the active clamp circuit (30) includes
   a pull-down resistor (32) connected between the source electrode (62) and the gate electrode (63) of the clamp transistor (60), and
   a clamp capacitor (31) connected between the drain electrode (29) of the GaN transistor (20) and the gate electrode (63) of the clamp transistor (60).

### [Clause 4]

The semiconductor device according to clause 3, further including:
a capacitor (80) connected between the source electrode (62) and the gate electrode (63) of the clamp transistor (60).

### [Clause 5]

The semiconductor device according to clause 3 or 4, further including:
a protective transistor (90) connected between the source electrode (62) and the gate electrode (63) of the clamp transistor (60) and including a gate electrode (93) electrically connected to the gate electrode (26) of the GaN transistor (20).

### [Clause 6]

The semiconductor device according to any one of clauses 3 to 5, in which
as viewed in a thickness-wise direction (z-direction) of the semiconductor substrate (11), the GaN transistor (20) and the clamp transistor (60) each include an active region (20T, 60T) that is rectangular and has a long-side direction and a short-side direction,
as viewed in the thickness-wise direction (z-direction) of the semiconductor substrate (11), the GaN transistor (20) and the clamp transistor (60) are arranged next to each other in the long-side direction of the GaN transistor (20), and
the long-side direction of the active region (20T) of the GaN transistor (20) is orthogonal to the long-side direction of the active region (60T) of the clamp transistor (60).

### [Clause 7]

The semiconductor device according to clause 6, in which as viewed in the long-side direction of the active region (20T) of the GaN transistor (20), the clamp capacitor (31) and the pull-down resistor (32) are arranged to overlap the drain pad (51) in the short-side direction of the active region (20T) of the GaN transistor (20).

### [Clause 8]

The semiconductor device according to any one of clauses 3 to 7, in which the clamp capacitor (31) includes a first electrode (31P) and a second electrode (31Q), and the pull-down resistor (32) includes a first terminal (32P) and a second terminal (32Q), the semiconductor device, further including:
a first interconnect (71) electrically connecting the first electrode (31P) of the clamp capacitor (31) and the drain electrode (29) of the GaN transistor (20);
a second interconnect (72) electrically connecting the second electrode (31Q) of the clamp capacitor (31) and the first terminal (32P) of the pull-down resistor (32) to the gate electrode (63) of the clamp transistor (60);
a third interconnect (73) electrically connecting the second terminal (32Q) of the pull-down resistor (32) and the source electrode (62) of the clamp transistor (60);
a fourth interconnect (74) electrically connecting the source electrode (62) of the clamp transistor (60) and the source electrode (28) of the GaN transistor (20); and
a fifth interconnect (75) electrically connecting the drain electrode (61) of the clamp transistor (60) and the gate electrode (26) of the GaN transistor (20).

### [Clause 9]

The semiconductor device according to clause 8, in which the first interconnect (71), the second interconnect (72), the third interconnect (73), the fourth interconnect (74), and the fifth interconnect (75) are formed on the semiconductor substrate (11).

### [Clause 10]

The semiconductor device according to clause 9, in which
as viewed in a thickness-wise direction (z-direction) of the semiconductor substrate (11), the semiconductor substrate (11) is rectangular and has a long-side direction and a short-side direction,
the GaN transistor (20) and the clamp transistor (60) are formed next to each other in the long-side direction of the semiconductor substrate (11), and
as viewed in the thickness-wise direction (z-direction) of the semiconductor substrate (11), the first interconnect (71), the second interconnect (72), the third interconnect (73), the fourth interconnect (74), and the fifth interconnect (75) are each arranged closer to the clamp transistor (60) in the long-side direction of the semiconductor substrate (11) than a center, in the long-side direction, of the semiconductor substrate (11) is.

### [Clause 11]

The semiconductor device according to any one of clauses 8 to 10, including:
a front interconnect layer (L1) in which the drain pad (51), the source pad (52), and the gate pad (53) are formed;
an intermediate interconnect layer (L2, L3) arranged closer to the semiconductor substrate (11) than the front interconnect layer (L1) is, the first interconnect (71), the second interconnect (72), the third interconnect (73), the fourth interconnect (74), and the fifth interconnect (75) being formed in the intermediate interconnect layer (L2, L3); and
a substrate-side interconnect layer (L4) arranged at a side of the intermediate interconnect layer (L2, L3) opposite from the front interconnect layer (L1), the GaN transistor (20) being formed in the substrate-side interconnect layer (L4),
in which the clamp transistor (60), the clamp capacitor (31), and the pull-down resistor (32) are arranged in the substrate-side interconnect layer (L4).

### [Clause 12]

The semiconductor device according to any one of clauses 3 to 11, further including:
an insulation layer (27) formed on the semiconductor substrate (11), in which
the clamp capacitor (31) includes
   a first electrode (31P) and a second electrode (31Q) separately arranged on the insulation layer (27), and
   a dielectric layer (33) arranged on the insulation layer (27) and sandwiched between the first electrode (31P) and the second electrode (31Q).

### [Clause 13]

The semiconductor device according to any one of clauses 3 to 12, further including:
a connection path (32A) electrically connecting the drain electrode (29) of the GaN transistor (20) and the source electrode (62) of the clamp transistor (60), in which
the connection path (32A) includes a serpentine portion (32B), and
the pull-down resistor (32) includes a resistance component of the serpentine portion (32B).

### [Clause 14]

The semiconductor device according to any one of clauses 3 to 12, in which
the pull-down resistor (32) includes
   a first interconnect part (32PA) including a first terminal (32P),
   a second interconnect part (32QA) including a second terminal (32Q), and
   a plate-shaped resistor part (32R) formed on the semiconductor substrate (11) and having a greater resistance than the first interconnect part (32PA) and the second interconnect part (32QA), and
the first interconnect part (32PA) and the second interconnect part (32QA) are arranged on the resistor part (32R) and electrically connected to the resistor part (32R).

### [Clause 15]

The semiconductor device according to any one of clauses 3 to 12, in which the pull-down resistor (32) is configured by a normally-on transistor and includes an on-resistance of the normally-on transistor.

### [Clause 16]

A semiconductor module (100), including:
the semiconductor device (10) according to any one of clauses 1 to 15;
an encapsulation resin (110) encapsulating the semiconductor device (10);
a drain terminal (121) exposed from the encapsulation resin (110) and electrically connected to the drain pad (51);

a source terminal (122) exposed from the encapsulation resin (110) and electrically connected to the source pad (52); and

a gate terminal (124) exposed from the encapsulation resin (110) and electrically connected to the gate pad (53).

### [Clause 17]

The semiconductor module (200) according to clause 16, in which the semiconductor device (10) includes multiple semiconductor devices, the semiconductor module (200), including:
a driver chip (210) including a driver circuit (211) separately driving the semiconductor devices (10/10A, 10B),
in which the encapsulation resin (220) encapsulates the semiconductor devices (10/10A, 10B) and the driver chip (210).

### [Clause 18]

The semiconductor module (200) according to clause 17, in which as viewed in a thickness-wise direction (z-direction) of the semiconductor substrate (10), the semiconductor devices (10/10A, 10B) are arranged in a first direction, and the driver chip (210) and the semiconductor devices (10/10A, 10B) are arranged in a second direction orthogonal to the first direction.

### [Clause 19]

The semiconductor device according to any one of clauses 1 to 15, in which the clamp transistor (60) is configured to be turned on earlier than the GaN transistor (20) in response to a rise of drain-source voltage of the GaN transistor (20).

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims and the clauses.

In an example, the configuration of the present disclosure may be applied to a pad-on-chip structure in which a source pad and a drain pad are arranged immediately above the main structure (active region) of an HEMT instead of a source pad and a drain pad being arranged on a location extending laterally from the main structure of the HEMT. The terminals of the GaN transistor and the clamp transistor may be electrically connected in a package on which the semiconductor device is mounted.

1. A semiconductor device, comprising:
a semiconductor substrate;
a GaN transistor formed on the semiconductor substrate and including a drain electrode, a source electrode, and a gate electrode;
an active clamp circuit formed on the semiconductor substrate and electrically connected to the GaN transistor, the active clamp circuit including a clamp transistor configured to be activated based on a rise of drain-source voltage of the GaN transistor;
a drain pad electrically connected to the drain electrode of the GaN transistor;
a source pad electrically connected to the source electrode of the GaN transistor; and
a gate pad electrically connected to the gate electrode of the GaN transistor.

2. The semiconductor device according to claim 1, wherein
the GaN transistor includes a main drift layer,
the clamp transistor includes a sub drift layer, and
the sub drift layer and the main drift layer are composed of a same material.

3. The semiconductor device according to claim 1, wherein
the clamp transistor includes a drain electrode, a source electrode, and a gate electrode,
the source electrode of the clamp transistor is electrically connected to the source electrode of the GaN transistor,
the drain electrode of the clamp transistor is electrically connected to the gate electrode of the GaN transistor, and
the active clamp circuit includes
a pull-down resistor connected between the source electrode and the gate electrode of the clamp transistor, and
a clamp capacitor connected between the drain electrode of the GaN transistor and the gate electrode of the clamp transistor.

4. The semiconductor device according to claim 3, further comprising:
a capacitor connected between the source electrode and the gate electrode of the clamp transistor.

5. The semiconductor device according to claim 3, further comprising:
a protective transistor connected between the source electrode and the gate electrode of the clamp transistor and including a gate electrode electrically connected to the gate electrode of the GaN transistor.

6. The semiconductor device according to claim 3, wherein
as viewed in a thickness-wise direction of the semiconductor substrate, the GaN transistor and the clamp transistor each include an active region that is rectangular and has a long-side direction and a short-side direction,
as viewed in the thickness-wise direction of the semiconductor substrate, the GaN transistor and the clamp transistor are arranged next to each other in the long-side direction of the GaN transistor, and
the long-side direction of the active region of the GaN transistor is orthogonal to the long-side direction of the active region of the clamp transistor.

7. The semiconductor device according to claim 6, wherein as viewed in the long-side direction of the active region of the GaN transistor, the clamp capacitor and the pull-down resistor are arranged to overlap the drain pad in the short-side direction of the active region of the GaN transistor.

8. The semiconductor device according to claim 3, wherein the clamp capacitor includes a first electrode and a second electrode, and the pull-down resistor includes a first terminal and a second terminal, the semiconductor device, further comprising:
a first interconnect electrically connecting the first electrode of the clamp capacitor and the drain electrode of the GaN transistor;
a second interconnect electrically connecting the second electrode of the clamp capacitor and the first terminal of the pull-down resistor to the gate electrode of the clamp transistor;
a third interconnect electrically connecting the second terminal of the pull-down resistor and the source electrode of the clamp transistor;
a fourth interconnect electrically connecting the source electrode of the clamp transistor and the source electrode of the GaN transistor; and
a fifth interconnect electrically connecting the drain electrode of the clamp transistor and the gate electrode of the GaN transistor.

9. The semiconductor device according to claim 8, wherein the first interconnect, the second interconnect, the third interconnect, the fourth interconnect, and the fifth interconnect are formed on the semiconductor substrate.

10. The semiconductor device according to claim 9, wherein
as viewed in a thickness-wise direction of the semiconductor substrate, the semiconductor substrate is rectangular and has a long-side direction and a short-side direction,
the GaN transistor and the clamp transistor are formed next to each other in the long-side direction of the semiconductor substrate, and
as viewed in the thickness-wise direction of the semiconductor substrate, the first interconnect, the second interconnect, the third interconnect, the fourth interconnect, and the fifth interconnect are each arranged closer to the clamp transistor in the long-side direction of the semiconductor substrate than a center, in the long-side direction, of the semiconductor substrate is.

11. The semiconductor device according to claim 8, comprising:
a front interconnect layer in which the drain pad, the source pad, and the gate pad are formed;
an intermediate interconnect layer arranged closer to the semiconductor substrate than the front interconnect layer is, the first interconnect, the second interconnect, the third interconnect, the fourth interconnect, and the fifth interconnect being formed in the intermediate interconnect layer; and
a substrate-side interconnect layer arranged at a side of the intermediate interconnect layer opposite from the front interconnect layer, the GaN transistor being formed in the substrate-side interconnect layer,
wherein the clamp transistor, the clamp capacitor, and the pull-down resistor are arranged in the substrate-side interconnect layer.

12. The semiconductor device according to claim 3, further comprising:
an insulation layer formed on the semiconductor substrate, wherein
the clamp capacitor includes
a first electrode and a second electrode separately arranged on the insulation layer, and
a dielectric layer arranged on the insulation layer and sandwiched between the first electrode and the second electrode.

13. The semiconductor device according to claim 3, further comprising:
a connection path electrically connecting the drain electrode of the GaN transistor and the source electrode of the clamp transistor, wherein
the connection path includes a serpentine portion, and
the pull-down resistor includes a resistance component of the serpentine portion.

14. The semiconductor device according to claim 3, wherein
the pull-down resistor includes
a first interconnect part including a first terminal,
a second interconnect part including a second terminal, and
a plate-shaped resistor part formed on the semiconductor substrate and having a greater resistance than the first interconnect part and the second interconnect part, and
the first interconnect part and the second interconnect part are arranged on the resistor part and electrically connected to the resistor part.

15. The semiconductor device according to claim 3, wherein the pull-down resistor is configured by a normally-on transistor and includes an on-resistance of the normally-on transistor.

16. A semiconductor module, comprising:
the semiconductor device according to claim 1;
an encapsulation resin encapsulating the semiconductor device;
a drain terminal exposed from the encapsulation resin and electrically connected to the drain pad;
a source terminal exposed from the encapsulation resin and electrically connected to the source pad; and
a gate terminal exposed from the encapsulation resin and electrically connected to the gate pad.
